(19) United States
(12) Patent Application Publication
(10) Pub. No.: US 2021/0389671 A1
(43) Pub. Date: Dec. 16, 2021

(54) RADIATION-SENSITIVE RESIN COMPOSITION AND RESIST PATTERN-FORMING METHOD

(71) Applicant: JSR CORPORATION, Tokyo (JP)

(72) Inventors: Tetsurou KANEKO, Tokyo (JP); Hiromitsu NAKASHIMA, Tokyo (JP); Yuushi MATSUMURA, Tokyo (JP); Junya SUZUKI, Tokyo (JP); Shuto MORI, Tokyo (JP); Hiroyuki ISHII, Tokyo (JP)

(73) Assignee: JSR CORPORATION, Tokyo (JP)

(21) Appl. No.: 17/458,783

(22) Filed: Aug. 27, 2021

Related U.S. Application Data
(63) Continuation of application No. PCT/JP2020/009224, filed on Mar. 4, 2020.

(30) Foreign Application Priority Data
Mar. 8, 2019 (JP) 2019-043129

(51) Int. Cl. G03F 7/038; G03F 7/20; G03F 7/004; G03F 7/32; G03F 7/38; G03F 7/40

(52) U.S. Cl. CPC G03F 7/0384; G03F 7/2006; G03F 7/40; G03F 7/322; G03F 7/38; G03F 7/0045

(57) ABSTRACT

A radiation-sensitive resin composition includes: a first polymer having a first structural unit which includes a phenolic hydroxyl group, and a second structural unit which includes an acid-labile group and a carboxy group which is protected by the acid-labile group; a second polymer having a third structural unit represented by the following formula (S-1), and a fourth structural unit which is a structural unit other than the third structural unit and is represented by the following formula (S-2); and a radiation-sensitive acid generator, wherein the acid-labile group includes a monocyclic or polycyclic ring structure having no fewer than 3 and no more than 20 ring atoms.

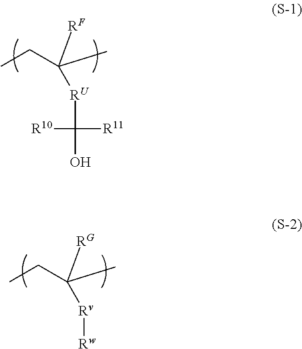

### CROSS-REFERENCE TO RELATED APPLICATIONS

The present application is a continuation application of International Application No. PCT/JP2020/009224, filed Mar. 4, 2020, which claims priority to Japanese Patent Application No. 2019-43129, filed Mar. 8, 2019. The contents of these applications are incorporated herein by reference in their entirety.

### BACKGROUND OF THE INVENTION

### Field of the Invention

The present invention relates to a radiation-sensitive resin composition and a resist pattern-forming method.

### Description of the Related Art

A radiation-sensitive composition for use in microfabrication by lithography generates an acid at a light-exposed region upon an irradiation with a radioactive ray, e.g., an electromagnetic wave such as a far ultraviolet ray such as an ArF excimer laser beam, a KrF excimer laser beam, etc., an extreme ultraviolet ray (EUV), or a charged particle ray such as an electron beam. A chemical reaction in which the acid serves as a catalyst causes a difference in rates of dissolution in a developer solution between light-exposed regions and light-unexposed regions, whereby a resist pattern is formed on a substrate.

Such a radiation-sensitive composition is required to result in superiority in not only resolution and rectangularity of a cross-sectional shape of the resist pattern but also in LWR (Line Width Roughness) performance, thereby enabling a highly precise pattern to be obtained with high process yield. To address such requirements, a structure of a polymer contained in the radiation-sensitive resin composition has been extensively studied, and it is known that incorporation of a lactone structure such as a butyrolactone structure or a norbornanelactone structure can serve to enhance adhesiveness of the resist pattern to the substrate and improve the aforementioned performance (see Japanese Unexamined Patent Applications, Publication Nos. H11-212265, 2003-5375, and 2008-83370).

### SUMMARY OF THE INVENTION

According to an aspect of the present invention, a radiation-sensitive resin composition includes a first polymer, a second polymer and a radiation-sensitive acid generator. The first polymer includes a first structural unit which includes a phenolic hydroxyl group, and a second structural unit which includes an acid-labile group and a carboxy group which is protected by the acid-labile group. The second polymer includes a third structural unit represented by formula (S-1), and a fourth structural unit which is a structural unit other than the third structural unit and is represented by formula (S-2). The acid-labile group includes a monocyclic or polycyclic ring structure having no fewer than 3 and no more than 20 ring atoms.

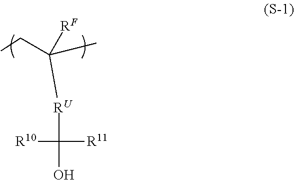

In the formula (S-1), R^{F} represents a hydrogen atom, a fluorine atom, or a monovalent organic group having 1 to 20 carbon atoms; R^{U} represents a single bond or a divalent organic group having 1 to 20 carbon atoms; R¹⁰ represents a fluorine atom or a monovalent fluorinated hydrocarbon group having 1 to 20 carbon atoms; and R¹¹ represents a hydrogen atom, a fluorine atom, a monovalent hydrocarbon group having 1 to 20 carbon atoms, or a monovalent fluorinated hydrocarbon group having 1 to 20 carbon atoms.

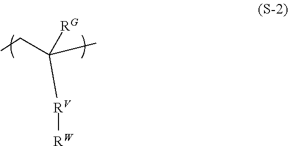

In the formula (S-2), R^{G} represents a hydrogen atom, a fluorine atom, or a monovalent organic group having 1 to 20 carbon atoms; R^{V} represents a single bond or a divalent organic group having 1 to 20 carbon atoms; and R^{W} represents a monovalent organic group having 1 to 20 carbon atoms which comprises a fluorine atom and does not comprise an alkali-labile group.

According to another aspect of the present invention, a resist pattern-forming method includes forming a resist film directly or indirectly on a substrate by applying the above-mentioned radiation-sensitive resin composition. The resist film is exposed. The resist film exposed is developed.

### DESCRIPTION OF EMBODIMENTS

Under current circumstances in which miniaturization of resist patterns has proceeded to a level in which line widths are no greater than 40 nm, required levels for the aforementioned performance are further elevated. Furthermore, recently, in conjunction with the miniaturization of resist patterns, there is also a requirement for superiority in each of exposure latitude and depth of focus (DOF).

According to one embodiment of the invention, a radiation-sensitive resin composition contains:

a first polymer(hereinafter, may be also referred to as “(A1) polymer” or “polymer (A1)”) having a first structural unit (hereinafter, may be also referred to as “structural unit (I)”) which includes a phenolic hydroxyl group, and a second structural unit (hereinafter, may be also referred to as “structural unit (II)”) which includes an acid-labile group (hereinafter, may be also referred to as “acid-labile group (a)”) and a carboxy group which is protected by the acid-labile group (a);

a second polymer (hereinafter, may be also referred to as “(A2) polymer” or “polymer (A2)”) having a third structural unit (hereinafter, may be also referred to as “structural unit (III)”) represented by the following formula (S-1), and a fourth structural unit (hereinafter, may be also referred to as “structural unit (IV)”) which is a structural unit other than the third structural unit and is represented by the following formula (S-2); and

a radiation-sensitive acid generator (hereinafter, may be also referred to as “(B) acid generator” or “acid generator (B)”), wherein

the acid-labile group (a) includes a monocyclic or polycyclic ring structure having no fewer than 3 and no more than 20 ring atoms.

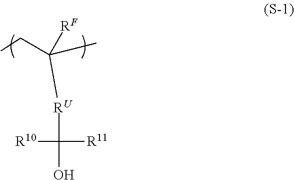

In the formula (S-1), R^{F} represents a hydrogen atom, a fluorine atom, or a monovalent organic group having 1 to 20 carbon atoms; R^{U} represents a single bond or a divalent organic group having 1 to 20 carbon atoms; R¹⁰ represents a fluorine atom or a monovalent fluorinated hydrocarbon group having 1 to 20 carbon atoms; and R¹¹ represents a hydrogen atom, a fluorine atom, a monovalent hydrocarbon group having 1 to 20 carbon atoms, or a monovalent fluorinated hydrocarbon group having 1 to 20 carbon atoms.

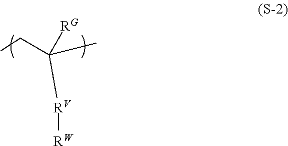

In the formula (S-2), R^{G} represents a hydrogen atom, a fluorine atom, or a monovalent organic group having 1 to 20 carbon atoms; R^{V} represents a single bond or a divalent organic group having 1 to 20 carbon atoms; and R^{W} represents a monovalent organic group having 1 to 20 carbon atoms which includes a fluorine atom and does not include an alkali-labile group.

According to another embodiment of the invention, a resist pattern-forming method includes: forming a resist film directly or indirectly on a substrate by applying the radiation-sensitive resin composition; exposing the resist film; and developing the resist film exposed.

The radiation-sensitive resin composition and the resist pattern-forming method of the embodiments of the present invention enable a resist pattern to be formed being superior in LWR performance, resolution, rectangularity of the cross-sectional shape, exposure latitude, and depth of focus. Therefore, these can be suitably used in the manufacture of semiconductor devices, in which further progress of miniaturization is expected in the future. Hereinafter, the embodiments of the present invention will be explained in detail.

### Radiation-Sensitive Resin Composition

According to one embodiment of the present invention, the radiation-sensitive resin composition contains the polymer (A1), the polymer (A2), and the acid generator (B). The radiation-sensitive resin composition may contain, as a favorable component, at least one of an acid diffusion controller (hereinafter, may be also referred to as “(C) acid diffusion controller” or “acid diffusion controller (C)”) and a solvent (hereinafter, may be also referred to as “(D) solvent” or “solvent (D)”), and may also contain other optional component(s) within a range not leading to impairment of the effects of the present invention.

The radiation-sensitive resin composition results in superiority in LWR performance, resolution, rectangularity of the cross-sectional shape, exposure latitude, and depth of focus (hereinafter, these types of performance may be also referred to collectively as “lithography performance”) due to containing the polymer (A1), the polymer (A2), and the acid generator (B). Although not necessarily clarified and without wishing to be bound by any theory, the reason for achieving the aforementioned effects by the radiation-sensitive resin composition due to involving such a constitution may be presumed, for example, as in the following. It is considered that the polymer (A1), which, in addition to the first structural unit which includes the phenolic hydroxyl group, has the second structural unit which includes the acid-labile group and the carboxy group protected by the acid-labile group, forms a main body of the resist film. On the other hand, it is considered that the polymer (A2) having: the third structural unit being represented by the above formula (S-1); and the fourth structural unit being represented by the above formula (S-2) localizes to a surface layer of the resist film. It is considered that when the resist film is exposed, a difference in solubility (dissolution contrast) between a light-exposed region and a light-unexposed region of the polymer (A2) which has localized to the surface layer of the resist film increases, improving the depth of focus as a result. In addition, it is considered that LWR performance, resolution, rectangularity of the cross-sectional shape, and exposure latitude are improved due to the polymer (A1) and the polymer (A2) having the structural units as described above.

The radiation-sensitive resin composition is to be used in exposure to an exposure light, described later. Of these, for example, as the exposure light, an extreme ultraviolet ray or an electron beam is preferred. Each of the extreme ultraviolet ray and the electron beam is comparatively high in energy, and the lithography performance resulting from the radiation-sensitive resin composition is superior even when exposed to such an extreme ultraviolet ray or electron beam. In other words, the radiation-sensitive resin composition is preferably to be used in exposure to an extreme ultraviolet ray or an electron beam. Each component of the radiation-sensitive resin composition will be described below.

### (A1) Polymer

The polymer (A1) is a polymer having the structural unit (I) and the structural unit (II). The polymer (A1) may be a polymer of one type having the structural unit (I) and the structural unit (II), and may be a mixture of polymers of multiple types, respectively having the structural unit (I) and the structural unit (II). Each structural unit will be described below.

### Structural Unit (I)

The structural unit (I) includes the phenolic hydroxyl group. “Phenolic hydroxyl group” as referred to herein is not limited to a hydroxy group directly bonding to a benzene ring, and means any hydroxy group directly bonding to an aromatic ring. Due to the polymer (A1) having the structural unit which includes the phenolic hydroxyl group, hydrophilicity of the resist film can be increased, solubility in a developer solution can be appropriately adjusted, and further, adhesiveness of the resist pattern to the substrate can be improved. Furthermore, in the case of exposure to KrF, exposure to EUV, or exposure to an electron beam, sensitivity of the radiation-sensitive resin composition can be further improved.

Examples of the structural unit (I) include structural units represented by the following formula (1), and the like.

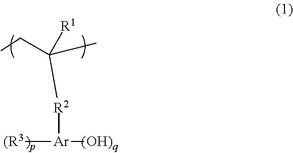

In the above formula (1), R¹ represents a hydrogen atom, a fluorine atom, a methyl group, or a trifluoromethyl group; R² represents a single bond, —O—, —COO—, or —CONH—; Ar represents a group obtained by removing (p+q+1) hydrogen atoms from an aromatic ring of an arene having 6 to 20 ring atoms; p is an integer of 0 to 10, wherein in a case in which p is 1, R³ represents a halogen atom or a monovalent organic group having 1 to 20 carbon atoms, in a case in which p is no less than 2, a plurality of R³s are identical or different and each R³ represents a halogen atom or a monovalent organic group having 1 to 20 carbon atoms, or no less than two of the plurality of R³s taken together represent a ring structure having 4 to 20 ring atoms together with the carbon chain to which the no less than two R³s bond; and q is an integer of 1 to 11, wherein a sum of p and q is no greater than 11.

In light of a degree of copolymerization of a monomer that gives the structural unit (I), R¹ represents preferably a hydrogen atom or a methyl group, and more preferably a hydrogen atom.

R² represents preferably a single bond or —COO—, and more preferably a single bond.

The number of “ring atoms” as referred to herein means the number of atoms constituting the ring in an alicyclic structure, an aromatic ring structure, an aliphatic heterocyclic structure, or an aromatic heterocyclic structure, and in the case of a polycyclic ring structure, the number of “ring atoms” means the number of atoms constituting the polycyclic ring.

Examples of the arene having 6 to 20 ring atoms that gives Ar include benzene, naphthalene, anthracene, phenanthrene, tetracene, pyrene, and the like. Of these, benzene and naphthalene are preferred, and benzene is more preferred.

The “organic group” as referred to herein means a group which includes at least one carbon atom. The monovalent organic group having 1 to 20 carbon atoms which may be represented by R³ is exemplified by: a monovalent hydrocarbon group having 1 to 20 carbon atoms; a group which includes a divalent hetero atom-containing group between two adjacent carbon atoms or at the end of the atomic bonding side of the monovalent hydrocarbon group having 1 to 20 carbon atoms; a group obtained by substituting with a monovalent hetero atom-containing group, a part or all of hydrogen atoms included in the monovalent hydrocarbon group having 1 to 20 carbon atoms or the divalent hetero atom-containing group; and the like.

The “hydrocarbon group” as referred to herein may include a chain hydrocarbon group, an alicyclic hydrocarbon group, and an aromatic hydrocarbon group. The “hydrocarbon group” may be either a saturated hydrocarbon group or an unsaturated hydrocarbon group. The “chain hydrocarbon group” as referred to herein means a hydrocarbon group not including a cyclic structure but being constituted with only a chain structure, and may be exemplified by both a linear hydrocarbon group and a branched hydrocarbon group. The “alicyclic hydrocarbon group” as referred to herein means a hydrocarbon group which includes, as a ring structure, not an aromatic ring structure but an alicyclic structure alone, and may be exemplified by both a monocyclic alicyclic hydrocarbon group and a polycyclic alicyclic hydrocarbon group. With regard to this, it is not necessary for the alicyclic hydrocarbon group to be constituted with only an alicyclic structure; it may include a chain structure in a part thereof. The “aromatic hydrocarbon group” as referred to herein means a hydrocarbon group which includes an aromatic ring structure as a ring structure. With regard to this, it is not necessary for the aromatic hydrocarbon group to be constituted with only an aromatic ring structure; it may include a chain structure or an alicyclic structure in a part thereof.

The monovalent hydrocarbon group having 1 to 20 carbon atoms is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

Examples of the monovalent chain hydrocarbon group having 1 to 20 carbon atoms include:

alkyl groups such as a methyl group, an ethyl group, an n-propyl group, and an i-propyl group;

alkenyl groups such as an ethenyl group, a propenyl group, and a butenyl group;

alkynyl groups such as an ethynyl group, a propynyl group, and a butynyl group; and the like.

Examples of the monovalent alicyclic hydrocarbon group having 3 to 20 carbon atoms include:

alicyclic saturated hydrocarbon groups such as a cyclopentyl group, a cyclohexyl group, a norbornyl group, an adamantyl group, a tricyclodecyl group, and a tetracyclodecyl group;

alicyclic unsaturated hydrocarbon groups such as a cyclopentenyl group, a cyclohexenyl group, a norbornenyl group, a tricyclodecenyl group, and a tetracyclodecenyl group; and the like.

Examples of the monovalent aromatic hydrocarbon group having 6 to 20 carbon atoms include:

aryl groups such as a phenyl group, a tolyl group, a xylyl group, a naphthyl group, and an anthryl group;

aralkyl groups such as a benzyl group, a phenethyl group, a naphthylmethyl group, and an anthrylmethyl group; and the like.

The hetero atom constituting the monovalent hetero atom-containing group and the divalent hetero atom-containing group is exemplified by an oxygen atom, a nitrogen atom, a sulfur atom, a phosphorus atom, a silicon atom, and a halogen atom. Examples of the halogen atom include a fluorine atom, a chlorine atom, a bromine atom, and an iodine atom.

Examples of the divalent hetero atom-containing group include —O—, —CO—, —S—, —CS—, —NR′—, a combination of two or more of these, and the like. R′ represents a hydrogen atom or a monovalent hydrocarbon group.

Examples of the monovalent hetero atom-containing. group include a halogen atom such as a fluorine atom, a chlorine atom, a bromine atom, or an iodine atom; a hydroxy group; a carboxy group; a cyano group; an amino group; a sulfanyl group; and the like.

R³ represents preferably the monovalent hydrocarbon group, and more preferably the alkyl group.

Examples of the ring structure having 4 to 20 ring atoms which may be constituted by the no less than two of the plurality of R³s taken together include aliphatic structures such as a cyclopentane structure, a cyclohexene structure, and the like.

p is preferably 0 to 2, more preferably 0 or 1, and still more preferably 0.

q is preferably 1 to 3, and more preferably 1 or 2.

Examples of the structural unit (I) include structural units (hereinafter, may be also referred to as “structural units (I-1) to (I-12)”) represented by the following formulae (1-1) to (1-12), and the like.

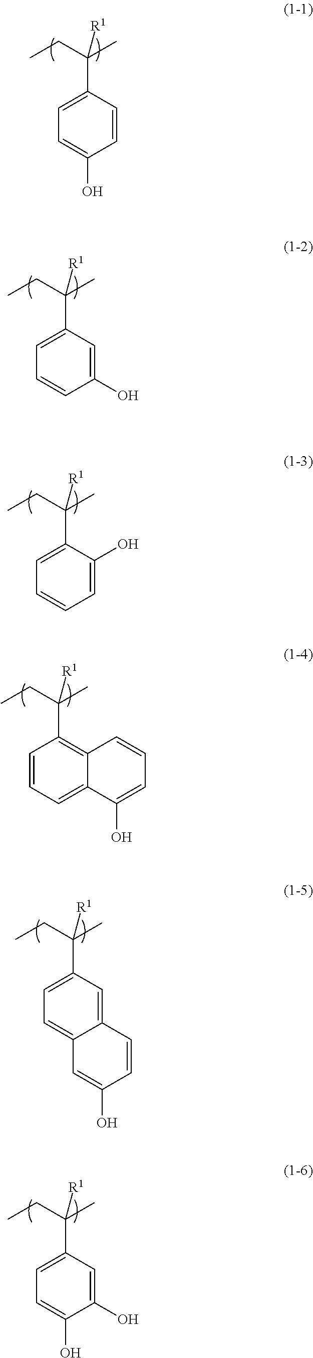

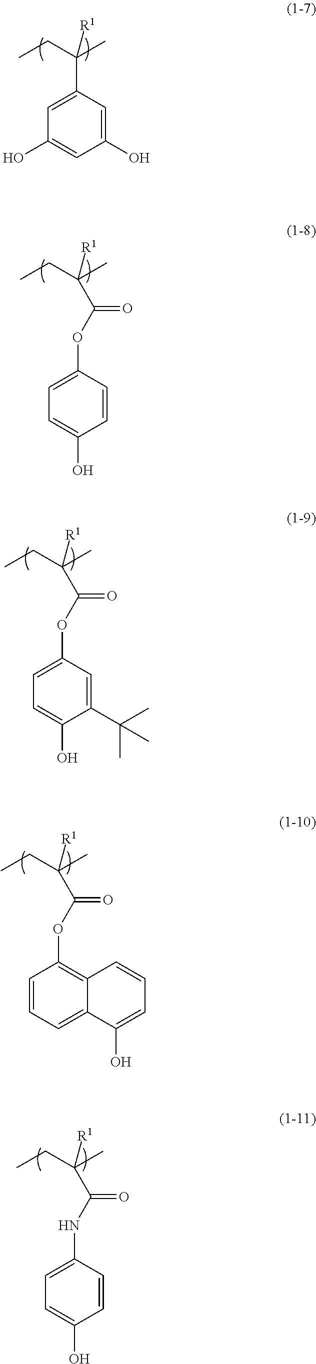

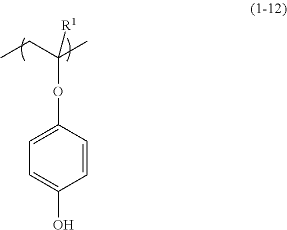

In the above formulae (1-1) to (1-12), R¹ is as defined in the above formula (1).

Of these, structural units (I-1) and (I-8) are preferred.

The lower limit of a proportion of the structural unit (I) contained with respect to total structural units constituting the polymer (A1) is preferably 10 mol %, more preferably 20 mol %, and still more preferably 30 mol %. The upper limit of the proportion is preferably 80 mol %, more preferably 70 mol %, and still more preferably 60 mol %. When the proportion of the structural unit (I) falls within the above range, the LWR performance, resolution, rectangularity of the cross-sectional shape, exposure latitude, and depth of focus resulting from the radiation-sensitive resin composition can be further improved.

### Structural Unit (II)

The structural unit (II) includes the acid-labile group (a) and the carboxy group protected by the acid-labile group (a). Furthermore, the acid-labile group (a) includes a monocyclic or polycyclic ring structure having 3 to 20 ring atoms. Due to the polymer (A1) containing the acid-labile group (a) in the structural unit (II), the acid-labile group (a) is dissociated by an action of an acid generated from the acid generator (B) by exposure, and solubility changes with respect to a developer solution of the polymer (A1), thereby enabling forming the resist pattern.

The “acid-labile group” as referred to herein means a group that substitutes for a hydrogen atom of a carboxy group, a phenolic hydroxyl group, or the like, and is dissociable by an action of an acid. Furthermore, “polycyclic” as referred to herein means a ring constituted by a plurality of monocyclic rings which have condensed together.

Examples of the structural unit (II) include structural units represented by the following formula (S-3), and the like. In the structural unit (II), —CR^{1A}R^{2A}R^{3A} bonding to an oxy-oxygen atom derived from the carboxy group corresponds to the acid-labile group (a).

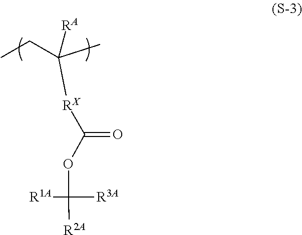

In the above formula (S-3), R^{A} represents a hydrogen atom, a fluorine atom, or a monovalent organic group having 1 to 20 carbon atoms; R^{X} represents a single bond or a divalent organic group having 1 to 20 carbon atoms; R^{1A} represents a hydrogen atom or a monovalent organic group having 1 to 20 carbon atoms; and R^{2A} represents a monovalent hydrocarbon group having 1 to 20 carbon atoms and R^{3A} represents a monovalent organic group having 1 to 20 carbon atoms, or R^{2A} and R^{3A} taken together represent a monocyclic or polycyclic ring structure having 3 to 20 ring atoms together with the carbon atom to which R^{2A} and R^{3A} bond, wherein in the case in which R^{2A} represents the monovalent hydrocarbon group having 1 to 20 carbon atoms and R^{3A} represents the monovalent organic group having 1 to 20 carbon atoms, at least one of R^{1A}, R^{2A}, and R^{3A} includes a monocyclic or polycyclic ring structure having 3 to 20 ring atoms.

In light of a degree of copolymerization of a monomer that gives the structural unit (II), R^{A} represents preferably a hydrogen atom or a methyl group.

R^{X} represents preferably a single bond.

The monovalent organic group having 1 to 20 carbon atoms which may be represented by R^{1A} is exemplified by groups similar to the monovalent organic groups having 1 to 20 carbon atoms exemplified as R³ in the above formula (1). This organic group is exemplified by a monovalent hydrocarbon group having 1 to 20 carbon atoms. Examples of this hydrocarbon group include groups similar to the hydrocarbon groups exemplified as R³ in the above formula (1), and the like. R^{1A} represents preferably a hydrogen atom, an alkyl group, or an aryl group, more preferably an alkyl group having no less than 3 carbon atoms, and still more preferably an alkyl group having 3 to 8 carbon atoms.

The monovalent hydrocarbon group having 1 to 20 carbon atoms which may be represented by R^{2A} is exemplified by groups similar to the monovalent hydrocarbon groups having 1 to 20 carbon atoms exemplified as R³ in the above formula (1), and the like.

The monovalent organic group having 1 to 20 carbon atoms which may be represented by R^{3A} is exemplified by groups similar to the monovalent organic groups having 1 to 20 carbon atoms exemplified as R³ in the above formula (1), and the like. Examples of this organic group include a monovalent organic group including a monocyclic or polycyclic ring structure having 3 to 20 ring atoms, a monovalent hydrocarbon group having 1 to 20 carbon atoms, a monovalent oxyhydrocarbon group having 1 to 20 carbon atoms, and the like.

The monovalent organic group including the monocyclic or polycyclic ring structure having 3 to 20 ring atoms which may be represented by R^{3A} is exemplified by a monovalent group including an alicyclic structure having 3 to 20 ring atoms, a monovalent group including an aliphatic heterocyclic structure having 3 to 20 ring atoms, a monovalent group including an aromatic ring structure having 3 to 20 ring atoms, a monovalent group including an aromatic heterocyclic structure having 3 to 20 ring atoms, and the like.

Examples of the alicyclic structure having 3 to 20 ring atoms include:

monocyclic saturated alicyclic structures such as a cyclopropane structure, a cyclobutane structure, a cyclopentane structure, and a cyclohexane structure;

polycyclic saturated alicyclic structures such as a norbornane structure, an adamantane structure, a tricyclodecane structure, and a tricyclododecane structure;

monocyclic unsaturated alicyclic structures such as a cyclopropene structure, a cyclobutene structure, a cyclopentene structure, and a cyclohexene structure;

polycyclic unsaturated alicyclic structures such as a norbornene structure, a tricyclodecene structure, and a tetracyclododecene structure; and the like.

Of these, the cyclopentane structure, the cyclohexane structure, the cyclohexene structure, or the adamantane structure is preferred.

Examples of the alicyclic heterocyclic structure having 3 to 20 ring atoms include:

lactone structures such as a butyrolactone structure, a valerolactone structure, a hexanolactone structure, and a norbornane lactone structure;

sultone structures such as a hexanosultone structure and a norbornanesultone structure;

oxygen atom-containing heterocyclic structures such as an oxacycloheptane structure and an oxanorbornane structure;

nitrogen atom-containing heterocyclic structures such as an azacyclohexane structure and a diazabicyclooctane structure;

sulfur atom-containing heterocyclic structures such as a thiacyclohexane structure and a thianorbornane structure; and the like.

Examples of the aromatic ring structure having 3 to 20 ring atoms include a benzene structure, a naphthalene structure, a phenanthrene structure, an anthracene structure, and the like.

Examples of the aromatic heterocyclic structure having 3 to 20 ring atoms include:

oxygen atom-containing heterocyclic structures such as a furan structure, a pyran structure, a benzofuran structure, and a benzopyran structure;

nitrogen atom-containing heterocyclic structures such as a pyridine structure, a pyrimidine structure, and an indole structure; and the like.

The monocyclic or polycyclic ring structure having 3 to 20 ring atoms which may be represented by R^{3A} is preferably an alicyclic structure having 5 to 10 ring atoms.

Examples of the monovalent hydrocarbon group having 1 to 20 carbon atoms which may be represented by R^{3A} include the hydrocarbon groups exemplified as R³ in the above formula (1).

Examples of the monovalent oxyhydrocarbon group having 1 to 20 carbon atoms which may be represented by R^{3A} include groups obtained from the hydrocarbon groups exemplified as R³ in the above formula (1) by substituting with an oxy group, a hydrogen atom bonding to a carbon atom constituting each of the hydrocarbon groups.

Examples of the monocyclic or polycyclic ring structure having 3 to 20 ring atoms which may be constituted by R^{2A} and R^{3A} include ring structures similar to the ring structures having 3 to 20 ring atoms included in the monovalent organic groups exemplified as R^{3A}.

In the case in which R^{2A} represents the monovalent hydrocarbon group and R^{3A} represents the monovalent organic group (i.e., in the case in which R^{2A} and R^{3A} do not constitute the ring structure), at least one of R^{1A}, R^{2A}, and R^{3A} includes a monocyclic or polycyclic ring structure having 3 to 20 ring atoms. Examples of such a ring structure include ring structures similar to the ring structures having 3 to 20 ring atoms included in the monovalent organic groups exemplified as R^{3A}.

The structural unit (II) is preferably a structural unit derived from 1-alkylcycloalkan-1-yl (meth)acrylate, a structural unit derived from 2-adamantylpropan-2-yl (meth)acrylate, a structural unit derived from cyclohexen-1-yl (meth)acrylate, or a structural unit derived from t-alkyloxystyrene.

The lower limit of a proportion of the structural unit (II) contained with respect to total structural units constituting the polymer (A1) is preferably 10 mol %, more preferably 20 mol %, and still more preferably 30 mol %. The upper limit of the proportion is preferably 80 mol %, more preferably 70 mol %, and still more preferably 60 mol %. When the proportion falls within the above range, the sensitivity of the radiation-sensitive resin composition can be further increased, and as a result, the LWR performance, resolution, rectangularity of the cross-sectional shape, exposure latitude, and depth of focus can be further improved.

### Other Structural Unit(s)

The polymer (A1) may contain other structural unit(s) within a range not leading to impairment of the effects of the present invention. A percentage content of the other structural unit(s) can be appropriately determined in accordance with purpose.

The other structural unit(s) is/are exemplified by a structural unit which is a structural unit other than the second structural unit (II) and includes an acid-labile group (b) (hereinafter, may be also referred to as “other structural unit which includes the acid-labile group (b)”). Exemplary structural units include a structural unit which includes the acid-labile group (b) not having a ring structure. Examples of the structural unit which includes the acid-labile group (b) not having a ring structure include a structural unit which includes the acid-labile group (b) and a phenolic hydroxyl group which is protected by the acid-labile group (b), a structural unit which includes the acid-labile group (b) and a carboxy group which is protected by the acid-labile group (b), and the like.

In the case in which the polymer (A1) contains the other structural unit which includes the acid-labile group (b), the lower limit of a proportion of the other structural unit which includes the acid-labile group (b) contained with respect to total structural units constituting the polymer (A1) is preferably 3 mol %, more preferably 5 mol %, and still more preferably 10 mol %. The upper limit of the proportion is preferably 40 mol %, more preferably 30 mol %, and still more preferably 20 mol %. Furthermore, in the case in which the polymer (A1) contains the other structural unit which includes the acid-labile group (b), the lower limit of a total of a proportion of the structural unit (II) and the proportion of structural unit(s) which include the acid-labile group (b) contained with respect to total structural units constituting the polymer (A1) is preferably 10 mol %, more preferably 20 mol %, and still more preferably 30 mol %. The upper limit of the total is preferably 80 mol %, more preferably 70 mol %, and still more preferably 60 mol %. When the proportion falls within the above range, the sensitivity of the radiation-sensitive resin composition can be further increased, and as a result, the LWR performance, resolution, rectangularity of the cross-sectional shape, exposure latitude, and depth of focus can be further improved.

The other structural unit(s) may also be exemplified by a structural unit which includes an alcoholic hydroxyl group such as, e.g., a structural unit derived from 3-hydroxyadamantan-1-yl (meth)acrylate. In the case in which the polymer (A1) has the structural unit which includes the alcoholic hydroxyl group, the upper limit of a proportion of the structural unit which includes the alcoholic hydroxyl group is preferably 80 mol %, more preferably 60 mol %, and still more preferably 45 mol %. The lower limit of the proportion is, for example, 1 mol %.

The other structural unit(s) may also be exemplified as a structural unit which includes at least one from the group consisting of a lactone structure, a cyclic carbonate structure, and a sultone structure (wherein a structural unit corresponding to the structural unit (I) or the structural unit (II) is excluded). Examples of the lactone structure include norbornane lactone structures such as a structural unit derived from norbornane lactone-yl (meth)acrylate, and the like. In the case in which the polymer (A1) has the structural unit which includes the at least one selected from the above group, the upper limit of a proportion thereof is preferably 70 mol %, more preferably 60 mol %, and still more preferably 50 mol %. The lower limit of the proportion is, for example, 1 mol %.

The lower limit of a polystyrene equivalent weight average molecular weight (Mw) of the polymer (A1) as determined by gel permeation chromatography (GPC) is preferably 2,000, more preferably 3,000, still more preferably 4,000, and particularly preferably 5,000. The upper limit of the Mw is preferably 50,000, more preferably 30,000, still more preferably 15,000, and particularly preferably 8,000. When the Mw of the polymer (A1) falls within the above range, the coating characteristics of the radiation-sensitive resin composition can be further improved.

The upper limit of a ratio (Mw/Mn) of the Mw to a polystyrene-equivalent number average molecular weight (Mn) of the polymer (A1) as determined by GPC is preferably 5, more preferably 3, still more preferably 2, and particularly preferably 1.8. The lower limit of the ratio is typically 1, preferably 1.1, and more preferably 1.2. When the Mw/Mn of the polymer (A1) falls within the above range, the coating characteristics of the radiation-sensitive resin composition can be further improved.

The Mw and Mn of the polymer as referred to herein are values determined using gel permeation chromatography (GPC) under the following conditions.

GPC columns: “G2000 HXL” x 2, “G3000 HXL” x 1, and “G4000 HXL” x 1, available from Tosoh Corporation;

flow rate: 1.0 mL/min

elution solvent: tetrahydrofuran

sample concentration: 1.0% by mass

amount of injected sample: 100 uL

column temperature: 40° C.

detector: differential refractometer

standard substance: mono-dispersed polystyrene

The lower limit of a content of the polymer (A1) with respect to total components other than the solvent (D) in the radiation-sensitive composition is preferably 40% by mass, more preferably 60% by mass, still more preferably 70% by mass, and particularly preferably 80% by mass. The upper limit of the content of the polymer (A1) is preferably 95% by mass with respect to the solid content.

### Synthesis Procedure of Polymer (A1)

The polymer (A1) may be synthesized by mixing each of monomers that give the structural unit (I), the structural unit (II), and, as needed, the other structural unit(s) in an appropriate molar percentage, and polymerizing a thus obtained mixture by a well-known procedure in the presence of a polymerization initiator such as azobisisobutyronitrile (AIBN). In a case in which the structural unit (I) is a structural unit derived from hydroxystyrene, hydroxyvinylnaphthalene, or the like, the structural unit can also be formed by using acetoxystyrene, acetoxyvinylnaphthalene, or the like to obtain a polymer component, and hydrolyzing the polymer component in the presence of a base such as triethylamine or the like. The polymer (A1) may be Obtained by mixing multiple types of polymers having the structural unit (I), the structural unit (II), and, as needed, the other structural unit(s), each being synthesized by the above procedure, or may be obtained by mixing a polymer having the structural unit (I) and, as needed, the other structural unit(s) with a polymer having the structural unit (II) and, as needed, the other structural unit(s). Furthermore, the polymer (A1) may be obtained by using preparative GPC or the like to fractionate appropriate parts of polymer(s) having the structural unit (I), the structural unit (II), and, as a necessary, the other structural unit(s), each being synthesized by polymerization using the above-described well-known procedure.

### (A2) Polymer

The polymer (A2) is a polymer having the structural unit (III) and the structural unit (IV). The polymer (A2) may be a polymer of one type having the structural unit (III) and the structural unit (IV), or may be a mixture of polymers of multiple types, respectively having the structural unit (III) and the structural unit (IV). Furthermore, the polymer (A2) may also have a fifth structural unit (hereinafter, may be also referred to as “structural unit (V)”). Each structural unit will be described below.

### Structural Unit (III)

The structural unit (III) is represented by the following formula (S-1).

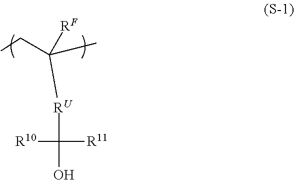

In the above formula (S-1), R^{F} represents a hydrogen atom, a fluorine atom, or a monovalent organic group having 1 to 20 carbon atoms; R^{U} represents a single bond or a divalent organic group having 1 to 20 carbon atoms; R¹⁰ represents a fluorine atom or a monovalent fluorinated hydrocarbon group having 1 to 20 carbon atoms; R¹¹ represents a hydrogen atom, a fluorine atom, a monovalent hydrocarbon group having 1 to 20 carbon atoms, or a monovalent fluorinated hydrocarbon group having 1 to 20 carbon atoms.

In light of a degree of copolymerization of a monomer that gives the structural unit (III), R^{F} represents preferably a hydrogen atom or a methyl group, and more preferably a hydrogen atom.

R^{U} represents preferably the single bond or —COO—.

The hydrocarbon group obtained by substitution with fluorine in the monovalent fluorinated hydrocarbon group having 1 to 20 carbon atoms which may be represented by each of R¹⁰ and R¹¹ is exemplified by groups similar to the hydrocarbon groups exemplified as R³ in the above formula (1), and the like.

Examples of the monovalent hydrocarbon group having 1 to 20 carbon atoms which may be represented by R¹¹ include groups similar to the hydrocarbon groups exemplified as R³ in the above formula (1), and the like.

The lower limit of a proportion of the structural unit (III) contained with respect to total structural units constituting the polymer (A2) is preferably 5 mol %, more preferably 10 mol %, still more preferably 15 mol %, and particularly preferably 20 mol %. The upper limit of the proportion is preferably 90 mol %, more preferably 80 mol %, still more preferably 70 mol %, and particularly preferably 65 mol %. When the proportion falls within the above range, the structural unit (III) can be sufficiently localized to the surface layer of the resist film, and as a result, the LWR performance, resolution, rectangularity of the cross-sectional shape, and depth of focus can be further improved.

### Structural Unit (IV)

The structural unit (IV) is represented by the following formula (S-2).

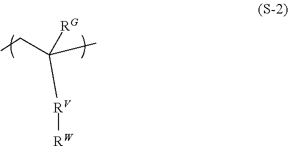

In the above formula (S-2), R^{G} represents a hydrogen atom, a fluorine atom, or a monovalent organic group having 1 to 20 carbon atoms; R^{V} represents a single bond or a divalent organic group having 1 to 20 carbon atoms; and R^{W} represents a monovalent organic group having 1 to 20 carbon atoms which includes a fluorine atom and does not include an alkali-labile group.

The “alkali-labile group” as referred to herein means a group which substitutes for a hydrogen atom in a polar functional group such as, for example, a hydroxy group or a sulfo group, and means a group which disassociates in the presence of an alkali (for example, in a 2.38% by mass aqueous tetramethylammonium hydroxide solution at 23° C.).

In light of a degree of copolymerization of a monomer that gives the structural unit (IV), R^{G} represents preferably a hydrogen atom or a methyl group, and more preferably a hydrogen atom.

R^{V} represents preferably the single bond or —COO—.

R^{W} is exemplified by a monovalent organic group having 1 to 20 carbon atoms which includes a fluorine atom and does not include —O—COO—. Examples of such an R^{W} include a monovalent fluorinated hydrocarbon group having 1 to 20 carbon atoms. The hydrocarbon group obtained by substitution with a fluorine atom in this fluorinated hydrocarbon group is exemplified by groups similar to the hydrocarbon groups exemplified as R³ in the above formula (1), and the like.

The lower limit of a proportion of the structural unit (IV) contained with respect to total structural units constituting the polymer (A2) is preferably 1 mol %, and more preferably 3 mol %. The upper limit of the proportion is preferably 30 mol %, and more preferably 25 mol %. When the proportion falls within the above range, the structural unit (IV) can be sufficiently localized to the surface layer of the resist film, and as a result, the LWR performance, resolution, rectangularity of the cross-sectional shape, exposure latitude, and depth of focus can be further improved.

### Structural Unit (V)

The structural unit (V) is a structural unit similar to the structural unit (II) contained in the polymer (A1), i.e., a structural unit represented, for example, by the above formula (S-3). Of structural units falling under this definition, R^{1A} in the structural unit (V) represented by the above formula (S-3) is preferably an alkyl group having no more than 2 carbon atoms, i.e., an alkyl group having 1 or 2 carbon atom(s). The structural unit (V) contained in the polymer (A2) may be identical or different from the structural unit (II) contained in the polymer (A1). For example, there may be a case in which R^{1A} in the structural unit (II) included in the polymer (A1) is an alkyl group having no fewer than 3 carbon atoms, and R^{1A} in the structural unit (V) included in the polymer (A2) is an alkyl group having no more than 2 carbon atoms.

When the polymer (A2) has the structural unit (V), the dissolution contrast between a light-exposed region and a light-unexposed region of the surface layer of the resist film with respect to the solvent (D) increases, and as a result, the LWR performance, resolution, rectangularity of the cross-sectional shape, exposure latitude, and depth of focus can be further improved.

In a case in which the polymer (A2) has the structural unit (V), the lower limit of a proportion of the structural unit (V) contained with respect to total structural units constituting the polymer (A2) is preferably 30 mol %, more preferably 45 mol %, still more preferably 55 mol %, and particularly preferably 65 mol %. The upper limit of the proportion is preferably 90 mol %, and more preferably 85 mol %. When the proportion falls within the above range, the dissolution contrast between the light-exposed region and the light-unexposed region of the surface layer of the resist film with respect to the solvent (D) increases, and as a result, the LWR performance, resolution, rectangularity of the cross-sectional shape, exposure latitude, and depth of focus can be further improved.

Furthermore, in the case in which the polymer (A2) has the structural unit (V), a molar percentage of the structural unit (V) in the polymer (A2) is preferably greater than the sum of, in the polymer (A1), the molar percentage of the structural unit (II) and the molar percentage of the other structural unit which includes the acid-labile group (b). More specifically, in a case in which the polymer (A1) has only the structural unit (II) as a structural unit which includes an acid-labile group, the molar percentage of the structural unit (V) in the polymer (A2) is preferably greater than the molar percentage of the structural unit (II) in the polymer (A1). In such a case, a difference between the molar percentage of the structural unit (V) in the polymer (A2) and the molar percentage of the structural unit (II) in the polymer (A1) is preferably no less than 1 mol %, and more preferably no less than 5 mol %. On the other hand, in the case in which the polymer (A1) has the structural unit (II) and the other structural unit which includes the acid-labile group (b) as structural units which include an acid-labile group, the molar percentage of the structural unit (V) in the polymer (A2) is preferably greater than the sum of, in the polymer (A1), the molar percentage of the structural unit (II) and the molar percentage of the other structural unit which includes the acid-labile group (b). In such a case, a difference between the molar percentage of the structural unit (V) in the polymer (A2) and the sum of, in the polymer (A1), the molar percentage of the structural unit (II) and the molar percentage of the other structural unit which includes the acid-labile group (b) is preferably no less than 1 mol %, and more preferably no less than 5 mol %.

When the molar percentage of the structural unit (V) in the polymer (A2) is thus greater than the sum of, in the polymer (A1), the molar percentage of the structural unit (II) and the molar percentage of the other structural unit which includes the acid-labile group (b), the dissolution contrast between the light-exposed region and the light-unexposed region of the surface layer of the resist film with respect to the solvent (D) increases, whereby the LWR performance, resolution, rectangularity of the cross-sectional shape, exposure latitude, and depth of focus can be further improved. In this case, it is preferable that: R^{1A} in the above formula (S-3), representing the structural unit (II) of the polymer (A1) represents an alkyl group having no fewer than 3 carbon atoms; and R^{1A} in the above formula (S-3), representing the structural unit (V) of the polymer (A2), represents an alkyl group having no more than 2 carbon atoms.

### Other Structural Unit(s)

The polymer (A2) may contain other structural unit(s) within a range not leading to impairment of the effects of the present invention. Proportion(s) of the other structural unit(s) can be appropriately determined in accordance with the purpose. The other structural unit(s) are exemplified by the above-mentioned other structural unit(s) contained in the polymer (A1).

For example, in the case in which the polymer (A2) contains the above-mentioned other structural unit which includes the acid-labile group (b), the lower limit of the proportion of the other structural unit which includes the acid-labile group (b) contained with respect to total structural units constituting the polymer (A2) is preferably 3 mol %, more preferably 5 mol %, and still more preferably 10 mol %. The upper limit of the proportion is preferably 40 mol %, more preferably 30 mol %, and still more preferably 20 mol %. In the case in which the polymer (A2) thus contains the other structural unit which includes the acid-labile group (b), the lower limit of a sum of the proportion of the structural unit (V) and the proportion of the structural unit(s) which include the acid-labile group (b) contained with respect to total structural units constituting the polymer (A2) is preferably 30 mol %, more preferably 45 mol %, still more preferably 55 mol %, and particularly preferably 65 mol %. The upper limit of the sum is preferably 90 mol %, and more preferably 85 mol %. When the proportion falls within the above range, the dissolution contrast between the light-exposed region and the light-unexposed region of the surface layer of the resist film with respect to the solvent (D) increases, and as a result, the LWR performance, resolution, rectangularity of the cross-sectional shape, exposure latitude, and depth of focus can be further improved.

It is to be noted that as described above, in the case in which the molar percentage of the structural unit (V) in the polymer (A2) is greater than the sum of, in the polymer (A1), the molar percentage of the structural unit (II) and the molar percentage of the other structural unit which includes the acid-labile group (b), the sum, in the polymer (A2), of the molar percentage of the structural unit (V) and the molar percentage of the structural unit(s) which include the acid-labile group (b) is clearly greater than the sum, in the polymer (A2), of the molar percentage of the structural unit (V) and the molar percentage of the other structural unit which includes the acid-labile group (b).

The lower limit of the Mw of the polymer (A2) is preferably 2,000, more preferably 3,000, still more preferably 4,000, and particularly preferably 5,000. The upper limit of the Mw is preferably 50,000, more preferably 30,000, and still more preferably 15,000. When the Mw of the polymer (A2) falls within the above range, the coating characteristics of the radiation-sensitive resin composition can be further improved.

The upper limit of a ratio (Mw/Mn) of a polystyrene-equivalent number average molecular weight (Mn) of the polymer (A2) as determined by GPC with respect to the Mw is preferably 5, more preferably 3, still more preferably 2, and particularly preferably 1.8. The lower limit of the ratio is typically 1, preferably 1.1, and more preferably 1.2. When the Mw/Mn of the polymer (A2) falls within the above range, the coating characteristics of the radiation-sensitive resin composition can be further improved.

The lower limit of the content of the polymer (A2) with respect to 100 parts by mass of the polymer (A1) is preferably 1 part by mass, and more preferably 5 parts by mass. The upper limit of the content is preferably 30 parts by mass, and more preferably 25 parts by mass.

### Synthesis Procedure of Polymer (A2)

The polymer (A2) can be synthesized similarly to the polymer (A1) by, for example, polymerizing a monomer that gives each structural unit according to a well-known procedure.

### (B) Acid Generator

The acid generator (B) is a substance which generates an acid (hereinafter, may be also referred to as “acid (b)”) by irradiation with a radioactive ray. Examples of the radioactive ray include electromagnetic waves such as a visible light ray, an ultraviolet ray, a far ultraviolet ray, EUV, an X-rays, and a γ-ray, charged particle rays such as an electron beam and a α-rays, and the like. The acid-labile group (a) included in the polymer (A1) and the acid-labile group (a) optionally included in the polymer (A2) are disassociated by an action of the acid (b) generated from the acid generator (B), thereby generating a carboxy group and changing the solubility of the polymer (A1) and optionally the polymer (A2) in the developer solution; accordingly, a resist pattern can be formed from the radiation-sensitive resin composition. The acid generator (B) may be contained in the radiation-sensitive resin composition either in the form of a low-molecular-weight compound (hereinafter, may be also referred to as “(B) acid generating agent” or “acid generating agent (B)”) or in the form of an acid generator incorporated as a part of a polymer such as the polymer (A1), the polymer (A2), and/or the like, or may be in a combination of both these forms.

The lower limit of a temperature at which the acid (b) disassociates the acid-labile group (a) is preferably 80° C., more preferably 90° C., and still more preferably 100° C. The upper limit of the temperature is preferably 130° C., more preferably 120° C., and still more preferably 110° C. The lower limit of a time period for the acid (b) to disassociate the acid-labile group (a) is preferably 10 sec, and more preferably 1 min. The upper limit of the time period is preferably 10 min, and more preferably 2 min.

Examples of the acid generated from the acid generator (B) include sulfonic acid, imidic acid, and the like.

The acid generating agent (B) is exemplified by an onium salt compound, an N-sulfonyloxyimide compound, a sulfonimide compound, a halogen-containing compound, a diazoketone compound, and the like.

Examples of the onium salt compound include a sulfonium salt, a tetrahydrothiophenium salt, an iodonium salt, a phosphonium salt, a diazonium salt, a pyridinium salt, and the like.

Specific examples of the acid generating agent (B) include compounds disclosed in paragraphs [0080] to [0113] of Japanese Unexamined Patent Application, Publication No. 2009-134088, and the like.

The acid generating agent (B) that generates sulfonic acid by irradiation with a radioactive ray is exemplified by a compound (hereinafter, may be also referred to as “compound (3)”) represented by the following formula (3), and the like. It is considered that due to the acid generating agent (B) having the following structure, a diffusion length in the resist film of the acid (b) generated is more properly reduced by interaction with the polymer (A1) and optionally the polymer (A2), and the like, and as a result, the lithography performance resulting from the radiation-sensitive resin composition can be further improved.

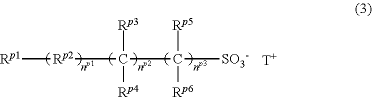

In the above formula (3), R^{p1} represents a monovalent group which includes a ring structure having no fewer than 5 ring atoms; R^{p2} represents a divalent linking group; R^{p3} and R^{p4} each independently represent a hydrogen atom, a fluorine atom, a monovalent hydrocarbon group having 1 to 20 carbon atoms, or a monovalent fluorinated hydrocarbon group having 1 to 20 carbon atoms; R^{p5} and R^{p6} each independently represent a fluorine atom or a monovalent fluorinated hydrocarbon group having 1 to 20 carbon atoms; n^{p1} is an integer of 0 to 10, n^{p2} is an integer of 0 to 10, and n^{p3} is an integer of 0 to 10, wherein a sum of n^{p1}, n^{p2}, and n^{p3} is no less than 1 and no greater than 30; in a case in which n^{p1} is no less than 2, a plurality of R^{p2}s are identical or different from each other; in a case in which np2 is no less than 2, a plurality of R^{p3}s are identical or different from each other, and a plurality of R^{p4}s are identical or different from each other; in a case in which n^{p3} is no less than 2, a plurality of R^{p5}s are identical or different from each other, and a plurality of R^{p6}s are identical or different from each other; and T⁺ represents a monovalent radiation-sensitive onium cation.

The monovalent group which includes a ting structure having no fewer than 5 ring atoms which is represented by R^{p1} is exemplified by a monovalent group which includes an alicyclic structure having no fewer than 5 ring atoms, a monovalent group which includes an aliphatic heterocyclic structure having no fewer than 5 ring atoms, a monovalent group which includes an aromatic ring structure having no fewer than 5 ring atoms, a monovalent group which includes an aromatic heterocyclic structure having no fewer than 5 ring atoms, and the like.

Examples of the alicyclic structure having no fewer than 5 ring atoms include:

monocyclic saturated alicyclic structures such as a cyclopentane structure, a cyclohexane structure, a cycloheptane structure, a cyclooctane structure, a cyclononane structure, a cyclohexane structure, and a cyclododecane structure;

monocyclic unsaturated alicyclic structures such as a cyclopentene structure, a cyclohexene structure, a cycloheptene structure, a cyclooctene structure, and a cyclodecene structure;

polycyclic saturated alicyclic structures such as a norbornane structure, an adamantane structure, a tricyclodecane structure, and a tricyclododecane structure;

polycyclic unsaturated alicyclic structures such as a norbornene structure, and a tricyclodecene structure; and the like.

Examples of the alicyclic heterocyclic structure having no fewer than 5 ring atoms include:

lactone structures such as a hexanolactone structure and a norbornanelactone structure;

sultone structures such as a hexanosultone structure and a norbornanesultone structure;

oxygen atom-containing heterocyclic structures such as an oxacycloheptane structure and an oxanorbornane structure;

nitrogen atom-containing heterocyclic structures such as an azacyclohexane structure and a diazabicyclooctane structure;

sulfur atom-containing heterocyclic structures such as a thiacyclohexane structure and a thianorbornane structure; and the like.

Examples of the aromatic ring structure having no fewer than 5 ring atoms include a benzene structure, a naphthalene structure, a phenanthrene structure, an anthracene structure, and the like.

Examples of the aromatic heterocyclic structure having no fewer than 5 ring atoms include:

oxygen atom-containing heterocyclic structures such as a furan structure, a pyran structure, a benzofuran structure, and a benzoyran structure;

nitrogen atom-containing heterocyclic structures such as a pyridine structure, a pyrimidine structure, and an indole structure; and the like.

The lower limit of the number of ring atoms of the ring structure included in R^{p1} is preferably 6, more preferably 8, still more preferably 9, and particularly preferably 10. The upper limit of the number of ring atoms is preferably 15, more preferably 14, still more preferably 13, and particularly preferably 12. When the number of ring atoms falls within the above range, the above-described diffusion length of the acid can be more properly reduced, and as a result, the lithography performance resulting from the radiation-sensitive resin composition can be further improved.

A part or all of hydrogen atoms included in the ring structure of R^{p1} may be substituted with a substituent. Examples of the substituent include halogen atoms such as a fluorine atom, a chlorine atom, a bromine atom and an iodine atom, a hydroxy group, a carboxy group, a cyano group, a nitro group, an alkoxy group, an alkoxycarbonyl group, an alkoxycarbonyloxy group, an acyl group, an acyloxy group, and the like. Of these, the hydroxy group is preferred.

R^{p1} represents: preferably the monovalent group which includes the alicyclic structure having no fewer than 5 ring atoms, or the monovalent group which includes the aliphatic heterocyclic structure having no fewer than 5 ring atoms; more preferably a monovalent group which includes an alicyclic structure having no fewer than 9 ring atoms or a monovalent group which includes an aliphatic heterocyclic structure having no fewer than 9 ring atoms, still more preferably an adamantyl group, a hydroxyadamantyl group, a norbornanelactone-yl group, a norbornanesultone-yl group or a 5-oxo-4-oxatricyclo[4.3.1.1^{3.8}]undecan-yl group, and particularly preferably an adamantyl group.

Examples of the divalent linking group which may be represented by R^{p2} include a carbonyl group, an ether group, a carbonyloxy group, a sulfide group, a thiocarbonyl group, a sulfonyl group, a divalent hydrocarbon group, and the like. Of these, the carbonyloxy group, the sulfonyl group, an alkanediyl group, or a divalent alicyclic saturated hydrocarbon group is preferred; the carbonyloxy group or the divalent alicyclic saturated hydrocarbon group is more preferred; the carbonyloxy group or a norbornanediyl group is still more preferred; and the carbonyloxy group is particularly preferred.

The monovalent hydrocarbon group having 1 to 20 carbon atoms which may be represented by each of R^{p3} and R^{p4} is exemplified by an alkyl group having 1 to 20 carbon atoms, and the like. The monovalent fluorinated hydrocarbon group having 1 to 20 carbon atoms which may be represented by each of R^{p3} and R^{p4} is exemplified by a fluorinated alkyl group having 1 to 20 carbon atoms, and the like. R^{p3} and R^{p4} each represent: preferably a hydrogen atom, a fluorine atom, or the fluorinated alkyl group; more preferably a fluorine atom or a perfluoroalkyl group; and still more preferably a fluorine atom or a trifluoromethyl group.

The monovalent fluorinated hydrocarbon group having 1 to 20 carbon atoms which may be represented by each of R^{p5} and R^{p6} is exemplified by a fluorinated alkyl group having 1 to 20 carbon atoms, and the like. R^{p5} and R^{p6} each represent: preferably a fluorine atom or the fluorinated alkyl group, more preferably a fluorine atom or a perfluoroalkyl group, still more preferably a fluorine atom or a trifluoromethyl group, and particularly preferably a fluorine atom.

n^{p1} is preferably 0 to 5, more preferably 0 to 3, still more preferably 0 to 2, and particularly preferably 0 or 1.

n^{p2} is preferably 0 to 5, more preferably 0 to 2, still more preferably 0 or 1, and particularly preferably 0.

The lower limit of n^{p3} is preferably 1, and more preferably 2. When n^{p3} is no less than 1, strength of the acid generated from the compound (3) can be increased, and as a result, the lithography performance resulting from the radiation-sensitive resin composition can be further improved. The upper limit of n^{p3} is preferably 4, more preferably 3, and still more preferably 2.

The lower limit of the sum of n^{p1}, n^{p2}, and n^{p3} is preferably 2, and more preferably 4. The upper limit of the sum of n^{p1}, n^{p2}, and n^{p3} is preferably 20, and more preferably 10.

The monovalent radiation-sensitive onium cation represented by T⁺ is exemplified by a cation (hereinafter, may be also referred to as “cation(r-a)”) represented by the following formula (r-a), a cation (hereinafter, may be also referred to as “cation (r-b)”) represented by the following formula (r-b), a cation (hereinafter, may be also referred to as “cation r-c”) represented by the following formula (r-c), and the like.

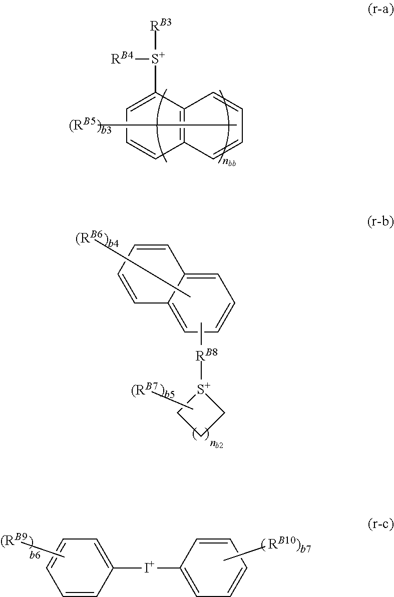

In the above formula (r-a), R^{B3} and R^{B4} each independently represent a monovalent organic group having 1 to 20 carbon atoms; b3 is an integer of 0 to 11, where in a case in which b3 is 1, R^{B5} represents a hydroxy group, a nitro group, a halogen atom, or a monovalent organic group having 1 to 20 carbon atoms, and in a case in which b³ is no less than 2, a plurality of R^{B5}s are identical or different from each other, and each R^{B5} represents a hydroxy group, a nitro group, a halogen atom, or a monovalent organic group having 1 to 20 carbon atoms, or the plurality of R^{B5}s taken together represent a ring structure having 4 to 20 ring atoms, together with the carbon chain to which the plurality of R^{B5}s bond; and n_{bb} is an integer of 0 to 3.

The monovalent organic group having 1 to 20 carbon atoms which may be represented by each of R^{B3}, R^{B4}, and R^{B5} is exemplified by: a monovalent hydrocarbon group having 1 to 20 carbon atoms; a monovalent group (g) which includes a divalent hetero atom-containing group between two adjacent carbon atoms of the monovalent hydrocarbon group having 1 to 20 carbon atoms, or at an end on an atomic bonding side of the monovalent hydrocarbon group having 1 to 20 carbon atoms; a monovalent group obtained by substituting with a hetero atom-containing group, a part or all of hydrogen atoms included in the monovalent hydrocarbon group having 1 to 20 carbon atoms or the monovalent group (g); and the like.

R^{B3} and R^{B4} each represent: preferably a monovalent unsubstituted hydrocarbon group having 1 to 20 carbon atoms or a hydrocarbon group obtained therefrom by substituting a hydrogen atom included therein with a substituent, more preferably a monovalent unsubstituted aromatic hydrocarbon group having 6 to 18 carbon atoms or an aromatic hydrocarbon group obtained therefrom by substituting a hydrogen atom included therein with a substituent, still more preferably a substituted or unsubstituted phenyl group, and particularly preferably an unsubstituted phenyl group.

The substituent which may substitute for the hydrogen atom included in the monovalent hydrocarbon group having 1 to 20 carbon atoms which may be represented by each of R^{B3} and R^{B4} is preferably a substituted or unsubstituted monovalent hydrocarbon group having 1 to 20 carbon atoms, —OSO₂—R^{k}, —SO₂—R^{k}, —OR^{k}, —COOR^{k}, —O—CO—R^{k}, —O—R^{kk}—COOR^{k}, —R^{kk}—CO—R^{k}, or —S—R^{k}, wherein R^{k} represents a monovalent hydrocarbon group having 1 to 10 carbon atoms; and R^{kk} represents a single bond or a divalent hydrocarbon group having 1 to 10 carbon atoms.

R^{B5} represents preferably a substituted or unsubstituted monovalent hydrocarbon group having 1 to 20 carbon atoms, —OSO₂—R^{k}, —SO₂—R^{k}, —OR^{k}, —COOR^{k}, —O—CO—R^{k}, —O—R^{kk}—COOR^{k}, —R^{kk}—CO—R^{k}, or —S—R^{k}, wherein R^{k} represents a monovalent hydrocarbon group having 1 to 10 carbon atoms; and R^{kk} represents a single bond or a divalent hydrocarbon group having 1 to 10 carbon atoms.

In the above formula (r-b), b4 is an integer of 0 to wherein in a case in which b4 is 1, R^{B6} represents a hydroxy group, a nitro group, a halogen atom, or a monovalent organic group having 1 to 20 carbon atoms, and in a case in which b4 is no less than 2, a plurality of R^{B6}s are identical or different from each other, and each R^{B6} represents a hydroxy group, a nitro group, a halogen atom, or a monovalent organic group having 1 to 20 carbon atoms, or the plurality of R^{B6}s taken together represent a ring structure having 4 to 20 ring atoms together with the carbon chain to which the plurality of R^{B6}s bond; b5 is an integer of 0 to 10, wherein in a case in which b5 is 1, R^{B7} represents a hydroxy group, a nitro group, a halogen atom, or a monovalent organic group having 1 to 20 carbon atoms, and in a case in which b5 is no less than 2, a plurality of R^{B7}s are identical or different from each other, and each R^{B7} represents a hydroxy group, a nitro group, a halogen atom, or a monovalent organic group having 1 to 20 carbon atoms, or the plurality of R^{B7}s taken together represent a ring structure having 3 to 20 ring atoms together with the carbon atom or carbon chain to which the plurality of R^{B7}s bond; n_{b2} is an integer of 0 to 3; R^{B8} represents a single bond or a divalent organic group having 1 to 20 carbon atoms; and n_{b1} is an integer of 0 to 2.

R^{B6} and R^{B7} each represent preferably a substituted or unsubstituted monovalent hydrocarbon group having 1 to 20 carbon atoms, —OR^{k}, —COOR^{k}, —O—CO—R^{k}, —O—R^{kk}—COOR^{k}, or —R^{kk}—CO—R^{k} wherein R^{k} represents a monovalent hydrocarbon group having 1 to 10 carbon atoms; and R^{kk} represents a single bond or a divalent hydrocarbon group having 1 to 10 carbon atoms.

In the above formula (r-c), b6 is an integer of 0 to 5, wherein in a case in which b6 is 1, R^{B9} represents a hydroxy group, a nitro group, a halogen atom, or a monovalent organic group having 1 to 20 carbon atoms, and in a case in which b6 is no less than 2, a plurality of R^{B9}s are identical or different from each other, and each R^{B9} represents a hydroxy group, a nitro group, a halogen atom, or a monovalent organic group having 1 to 20 carbon atoms, or the plurality of R^{B9}s taken together represent a ring structure having 4 to 20 ring atoms together with the carbon chain to which the plurality of R^{B9}s bond; and b7 is an integer of 0 to 5, wherein in a case in which b7 is 1, R^{B10} represents a hydroxy group, a nitro group, a halogen atom, or a monovalent organic group having 1 to 20 carbon atoms, and in a case in which b7 is no less than 2, a plurality of R^{B10}s are identical or different from each other, and each R^{B10} represents a hydroxy group, a nitro group, a halogen atom, or a monovalent organic group having 1 to 20 carbon atoms, or the plurality of R^{B10}s taken together represent a ring structure having 4 to 20 ring atoms together with the carbon chain to which the plurality of R^{B10}s bond.

R^{B9} and R^{B10} each represent preferably a substituted or unsubstituted monovalent hydrocarbon group having 1 to 20 carbon atoms, —OSO₂—R^{k}, —SO₂—R^{k}, —OR^{k}, —COOR^{k}, —O—CO—R^{k}, —O—R^{kk}13 COOR^{k}, —R^{kk}—CO—R^{k}, —S—R^{k}, or a ring structure taken together represented by at least two of these groups, wherein R^{k} represents a monovalent hydrocarbon group having 1 to 10 carbon atoms; and R^{kk} represents a single bond or a divalent hydrocarbon group having 1 to 10 carbon atoms.

Examples of the monovalent hydrocarbon group having 1 to 20 carbon atoms which may be represented by each of R^{B5}, R^{B6}, R^{B7}, R^{B9}, and R^{B10} include:

linear alkyl groups such as a methyl group, an ethyl group, an n-propyl group, and an n-butyl group;

branched alkyl groups such as an i-propyl group, an i-butyl group, a sec-butyl group, and a t-butyl group;

aryl groups such as a phenyl group, a tolyl group, a xylyl group, a methyl group, and a naphthyl group;

aralkyl groups such as a benzyl group and a phenethyl group; and the like.

Examples of the divalent organic group which may be represented by R^{B8} include groups obtained by removing one hydrogen atom from the monovalent organic groups having 1 to 20 carbon atoms exemplified as R^{B3}, R^{B4}, and R^{B5} in the above formula (r-a), and the like.

Examples of the substituent which may substitute for a hydrogen atom included in the hydrocarbon group which may be represented by each of R^{B5}, R^{B6}, R^{B7}, R^{B9}, and R^{B10} include: a halogen atom such as a fluorine atom, a chlorine atom, a bromine atom, or an iodine atom; a hydroxy group; a carboxy group; a cyano group; a nitro group; an alkoxy group; an alkoxycarbonyl group; an alkoxycarbonyloxy group; an acyl group; an acyloxy group; and the like. Of these, the halogen atom is preferred, and a fluorine atom is more preferred.

R^{B5}, R^{B6}, R^{B7}, R^{B9} and R^{B10} each represent preferably an unsubstituted linear or branched monovalent alkyl group, a monovalent fluorinated alkyl group, an unsubstituted monovalent aromatic hydrocarbon group, —OSO₂—R^{k}, or —SO₂—R^{k}, more preferably a fluorinated alkyl group or an unsubstituted monovalent aromatic hydrocarbon group, and still more preferably a fluorinated alkyl group.

In the formula (r-a), b3 is preferably 0 to 2, more preferably 0 or 1, and still more preferably 0; and n_{bb} is preferably 0 or 1, and more preferably 0. In the formula (r-b), b4 is preferably 0 to 2, more preferably 0 or 1, and still more preferably 0; b5 is preferably 0 to 2, more preferably 0 or 1, and still more preferably 0; n_{b2} is preferably 2 or 3, and more preferably 2; and n_{b1} is preferably 0 or 1, and more preferably 0. In the formula (r-c), each of b6 and b7 is preferably 0 to 2, more preferably 0 or 1, and still more preferably 0.

Of these, T⁺ represents preferably the cation (r-a), and more preferably a triphenylsulfonium cation.

Examples of the acid generating agent (B) include: compounds (hereinafter, may be also referred to as “compounds (3-1) to (3-20)”) represented by the following formulae (3-1) to (3-20) as an acid generating agent which generates sulfonic acid; compounds represented by the following formulae (4-1) to (4-3) (hereinafter, may be also referred to as “compounds (4-1) to (4-3)”) as an acid generating agent which generates imidic acid; and the like.

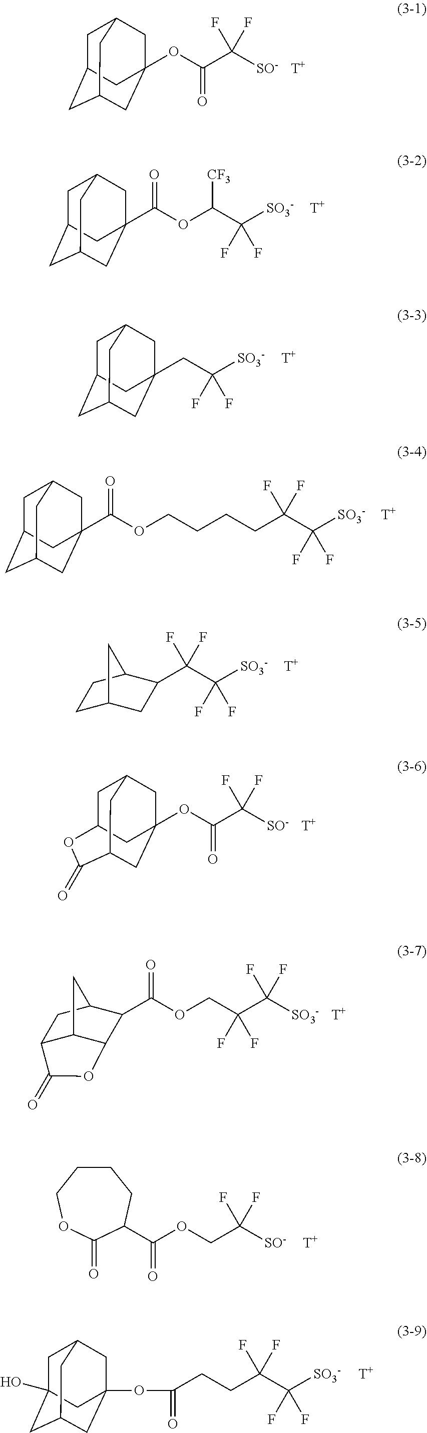

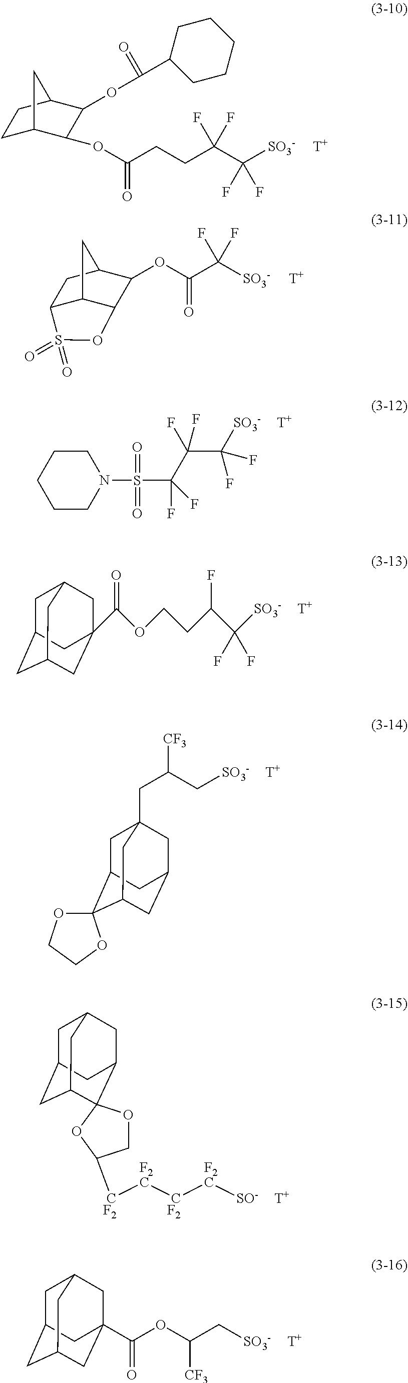

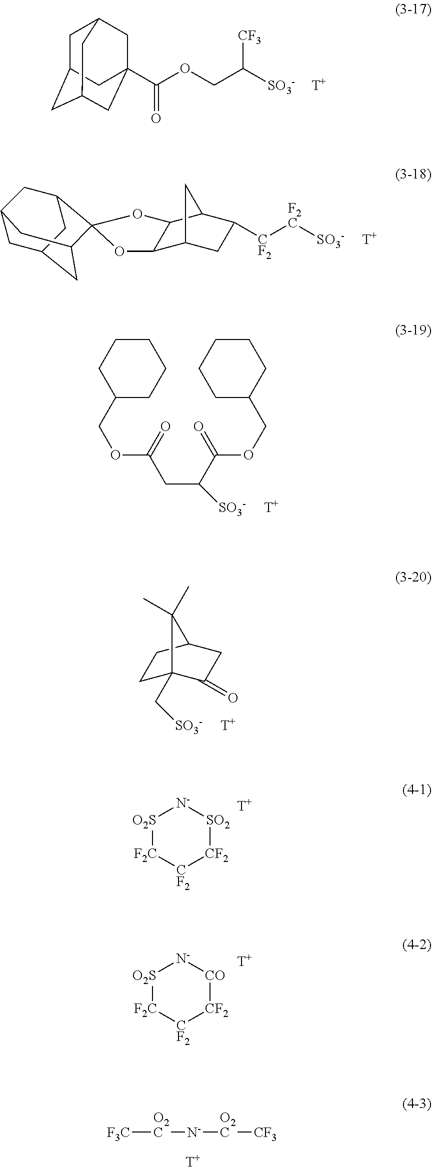

In the above formulae (3-1) to (3-20) and (4-1) to (4-3), T⁺ represents a monovalent radiation-sensitive onium cation.

Furthermore, the acid generator (B) may be exemplified as a polymer in which the structure of the acid generator is incorporated as a part of at least one of the polymer (A1) and the polymer (A2), e.g., a polymer having a structural unit represented by the following formula (3′).

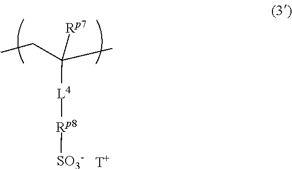

In the above formula (3′), R^{p7} represents a hydrogen atom or a methyl group; L⁴ represents a single bond, —COO—, or a divalent carbonyloxyhydrocarbon group; R^{p8} represents a fluorinated alkanediyl group having 1 to 10 carbon atoms; and T⁺ represents a monovalent radiation-sensitive onium cation.

In light of a degree of copolymerization of a monomer that gives the structural unit represented by the above formula (3′), R^{p7} represents preferably a hydrogen atom or a methyl group, and more preferably a methyl group.

L⁴ represents preferably the divalent carbonyloxyhydrocarbon group, and more preferably a carbonyloxyalkanediyl group or a carbonyl alkanediylarenediyl group.

R^{p8} represents preferably a fluorinated alkanediyl group having 1 to 4 carbon atoms, more preferably a perfluoroalkanediyl group having 1 to 4 carbon atoms, and still more preferably a hexafluoropropanediyl group.

The acid generating acid (B) is preferably the compound (3).

In the case in which the acid generator (B) is the acid generating agent (B), the lower limit of a content of the acid generating agent (B) with respect to 100 parts by mass of the polymer (A1) is preferably 0.1 parts by mass, more preferably 1 part by mass, and still more preferably 5 parts by mass. The upper limit of the content is preferably 70 parts by mass, more preferably 50 parts by mass, still more preferably 40 parts by mass, particularly preferably 30 parts by mass, and especially preferably 25 parts by mass. Further, also in the case in which the polymer (A2) includes the acid-labile group (a), the lower limit of a content of the acid generating agent (B) with respect to 100 parts by mass of the polymer (A1) and the polymer (A2) is preferably 0.1 parts by mass, more preferably 1 part by mass, and still more preferably 5 parts by mass. In the above-described case, the upper limit of the content is preferably 50 parts by mass, more preferably 40 parts by mass, still more preferably 30 parts by mass, and particularly preferably 25 parts by mass. When the content of the acid-generating agent (B) falls within the above range, the sensitivity and developability of the radiation-sensitive resin composition improve, and as a result, the LWR performance, resolution, rectangularity of the cross-sectional shape, and depth of focus can be further improved. Either one type, or two or more types of the acid generator (B) may be used.

### (C) Acid Diffusion Controller

The radiation-sensitive resin composition contains, as an optional component, the acid diffusion controller (C). The acid diffusion controller (C) controls a diffusion phenomenon, in the film, of the acid (b) generated from the acid generator (B) and the like upon exposure, thereby serving to inhibit unwanted chemical reactions in a light-unexposed region. Furthermore, storage stability of the radiation-sensitive resin composition is improved, and the resolution as a resist is further improved. Moreover, changes in line width of the resist pattern caused by variation of post-exposure time delay from the exposure until a development treatment can be suppressed, thereby enabling the radiation-sensitive resin composition to be obtained having superior process stability. The acid diffusion controller (C) may be contained in the radiation-sensitive resin composition in the form of a low-molecular weight compound (hereinafter, may be also referred to as “(C) acid diffusion control agent” or “acid diffusion control agent (C)”) or in the form of an acid diffusion controller incorporated as a part of a polymer such as the polymer (A1), the polymer (A2), or the like, or may be in a combination of both these forms.

Examples of the acid diffusion control agent (C) include a nitrogen atom-containing compound, a photodegradable base that is photosensitized by an exposure to generate a weak acid, and the like.

Examples of the nitrogen atom-containing compound include: amine compounds such as tripentylamine and trioctylamine; amide group-containing compounds such as formamide and N,N-dimethylacetamide; urea compounds such as urea and 1,1-dimethylurea; nitrogen-containing heterocyclic compounds such as pyridine, N-(undecylcarbonyloxyethyl) morpholine, and N-t-pentyloxycarbonyl-4-hydroxypiperidine; and the like.

The photodegradable base is exemplified by a compound containing a radiation-sensitive onium cation and an anion of a weak acid, and the like. In a light-exposed region, the photodegradable base generates a weak acid from: a proton generated upon degradation of the radiation-sensitive onium cation; and the anion of the weak acid, whereby acid diffusion controllability decreases.

Examples of the photodegradable base include compounds represented by the following formulae, and the like. Furthermore, a compound in which n^{p3} in the above formula (3) is 0 can also be used as the photodegradable base.

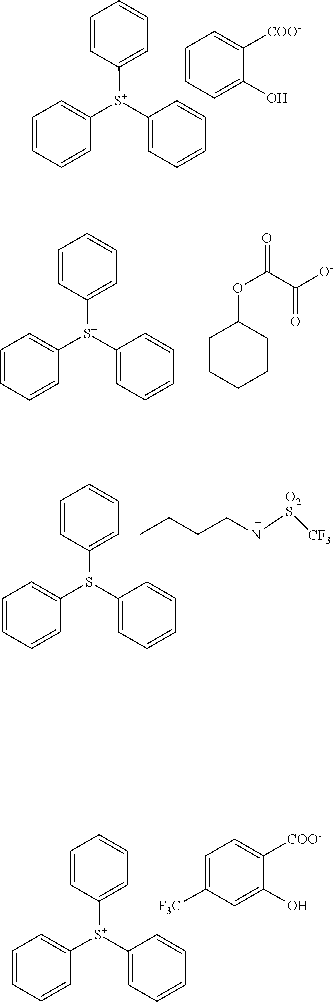

In the case in which the radiation-sensitive resin composition contains the acid diffusion control agent (C), the lower limit of a content of the acid diffusion control agent (C) with respect to 100 parts by mass of the polymer (A1) is preferably 0.1 parts by mass, more preferably 0.5 parts by mass, and still more preferably 1 part by mass. The upper limit of the content is preferably 20 parts by mass, more preferably 10 parts by mass, and still more preferably 5 parts by mass.

In the case in which the radiation-sensitive resin composition contains the acid diffusion control agent (C), the lower limit of a proportion of the acid diffusion control agent (C) with respect to 100 mol % of the acid generating agent (B) is preferably 1 mol %, more preferably 5 mol %, and still more preferably 10 mol %. The upper limit of the proportion is preferably 200 mol %, more preferably 100 mol %, and still more preferably 50 mol %.

When the content of the acid diffusion control agent (C) falls within the above range, the LWR performance, resolution, rectangularity of the cross-sectional shape, and depth of focus resulting from the radiation-sensitive resin composition can be further improved. Either one type, or two or more types of the acid diffusion controller (C) may be used.

### (D) Solvent

The radiation-sensitive resin composition typically contains the solvent (D). The solvent (D) is not particularly limited as long as it is a solvent capable of dissolving or dispersing at least the polymer (A1), the polymer (A2), and the acid generator (B), as well as the optional component(s) which is/are contained as desired.

The solvent (D) is exemplified by an alcohol solvent, an ether solvent, a ketone solvent, an amide solvent, an ester solvent, a hydrocarbon solvent, and the like.

Examples of the alcohol solvent include:

aliphatic monohydric alcohol solvents having 1 to 18 carbon atoms such as 4-methyl-2-pentanol and n-hexanol;

alicyclic, monohydric alcohol solvents having 3 to 18 carbon atoms such as cyclohexanol;

polyhydric alcohol solvents having 2 to 18 carbon atoms such as 1,2-propylene glycol;

polyhydric alcohol partial ether solvents having 3 to 19 carbon atoms such as propylene glycol-1-monomethyl ether; and the like.

Examples of the ether solvent include:

dialkyl ether solvents such as diethyl ether, dipropyl ether, dibutyl ether, dipentyl ether, diisoamyl ether, dihexyl ether, and diheptyl ether;

cyclic ether solvents such as tetrahydrofuran and tetrahydropyran;

aromatic ring-containing ether solvents such as diphenyl ether and anisole; and the like.

Examples of the ketone solvent include:

chain ketone solvents such as acetone, methyl ethyl ketone, methyl-n-propyl ketone, methyl-n-butyl ketone, diethyl ketone, methyl-iso-butyl ketone, 2-heptanone, ethyl-n-butyl ketone, methyl-n-hexyl ketone, di-iso-butyl ketone, and trimethylnonanone;

cyclic ketone solvents such as cyclopentanone, cyclohexanone, cycloheptanone, cyclooctanone, and methylcyclohexanone;

2,4-pentanedione, acetonylacetone, and acetophenone; and the like.

Examples of the amide solvent include:

cyclic amide solvents such as N,N-dimethylimidazolidinone and N-methylpyrrolidone;

cyclic amide solvents such as N-methylformamide, N,N-dimethylformamide, N,N-diethylformamide, acetamide, N-methylacetamide, N,N-dimethylacetamide, and N-methylpropionamide; and the like.

Examples of the ester solvent include:

monocarboxylic acid ester solvents such as n-butyl acetate and ethyl lactate;

polyhydric alcohol carboxylate solvents such as propylene glycol acetate;

polyhydric alcohol partial ether carboxylate solvents such as propylene glycol monomethyl ether acetate;

polyhydric carboxylic acid diester solvents such as diethyl oxalate;

carbonate solvents such as dimethyl carbonate and diethyl carbonate; and the like.

Examples of the hydrocarbon solvent include:

aliphatic hydrocarbon solvents having 5 to 12 carbon atoms such as n-heptane and n-hexane;

aromatic hydrocarbon solvents having 6 to 16 carbon atoms such as toluene and xylene; and the like.

Of these, at least one of the alcohol solvent, the ester solvent, and the ketone solvent is preferred, at least one selected from the group consisting of the polyhydric alcohol partial ether solvent, the polyhydric alcohol partial ether carboxylate solvent, and the cyclic ketone solvent is more preferred, and at least one selected from the group consisting of propylene glycol-1-monomethyl ether, propylene glycol monomethyl ether acetate, and cyclohexanone is still more preferred. Either one type, or two or more types of the solvent (D) may be used.

### Other Optional Component(s)

The other optional component(s) is/are exemplified by a surfactant and the like. The radiation-sensitive resin composition may contain one, or two or more types each of the other optional component(s).

The surfactant is a component that achieves the effect of improving coating properties, striation, developability, and the like. Examples of the surfactant include: nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate. Examples of a commercially available product of the surfactant include KP341 (available from Shin-Etsu Chemical Co., Ltd.), Polyflow No. 75 and Polyflow No. 95 (each available from Kyoeisha Chemical Co., Ltd.), EFTOP EF301, EFTOP EF303 and EFTOP EF352 (each available from available from Tohkem Products Corporation (Mitsubishi Materials Electronic Chemicals Co., Ltd.)), Megaface F171 and Megaface F173 (each available from DIC Corporation), Fluorad FC430 and Fluorad FC431 (each available from Sumitomo 3M Limited), ASAHI GUARD AG710, Surflon S-382, Surflon SC-101, Surflon SC-102, Surflon SC-103, Surflon SC-104, Surflon SC-105, and Surflon SC-106 (each available from Asahi Glass Co., Ltd.), and the like.

In the case in which the radiation-sensitive resin composition contains the surfactant, the upper limit of a content of the surfactant with respect to a total of 100 parts by mass of the polymer (A1) and the polymer (A2) is preferably 2 parts by mass. The lower limit of the content is, for example, 0.1 parts by mass.

### Preparation Procedure of Radiation-Sensitive Resin Composition

The radiation-sensitive resin composition may be prepared, for example, by mixing the polymer (A1), the polymer (A2), and the acid generator (B), as well as the other optional component(s) such as the acid diffusion controller (C) and/or the solvent (D), which is/are added as needed, in a certain ratio, and preferably filtering a thus resulting mixture through a membrane filter having a pore size of about 20 μm. The lower limit of a concentration of total components other than the solvent (D) in the radiation-sensitive resin composition is preferably 0.1% by mass, more preferably 0.5% by mass, still more preferably 1% by mass, and particularly preferably 1.5% by mass. The upper limit of the concentration of total components other than the solvent (D) is preferably 50% by mass, more preferably 30% by mass, still more preferably 10% by mass, and particularly preferably 5% by mass.

The radiation-sensitive resin composition may be used either for positive-tone pattern formation conducted using an alkaline developer solution, or for negative-tone pattern formation conducted using an organic solvent-containing developer solution.

### Resist Pattern-Forming Method

The resist pattern-forming method according to another embodiment of the present invention includes: a step of applying the radiation-sensitive resin composition of the one embodiment of the present invention directly or indirectly on a substrate (hereinafter, may be also referred to as “applying step”); a step of exposing the resist film formed by the applying step (hereinafter, may be also referred to as “exposing step”); and a step of developing the resist film exposed (hereinafter, may be also referred to as “developing step”).

According to the resist pattern-forming method, formation of a resist pattern is enabled with the LWR performance, resolution, rectangularity of the cross-sectional shape, exposure latitude, and depth of focus being superior due to use of the radiation-sensitive resin composition.

Hereinafter, each step will be described.

### Applying Step

In this step, the radiation-sensitive resin composition according to the one embodiment of the present invention is applied directly or indirectly on a substrate. Accordingly, a predetermined resist film is formed. The substrate is exemplified by a conventionally well-known substrate such as a silicon wafer, a wafer coated with silicon dioxide or aluminum, and the like. In addition, an organic or inorganic antireflective film disclosed in, for example, Japanese Examined Patent Application, Publication No. H6-12452, Japanese Unexamined Patent Application, Publication No. S59-93448, or the like may be provided on the substrate. An application procedure is exemplified by spin-coating, cast coating, roll-coating, and the like. After the application, prebaking, (PB) may be carried out as needed for evaporating the solvent remaining in the coating film. The lower limit of a temperature of the PB is preferably 60° C., and more preferably 80° C. The upper limit of the temperature is preferably 150° C., and more preferably 140° C. The lower limit of a PB time period is preferably 5 sec, and more preferably 10 sec. The lower limit of the time period is preferably 600 sec, and more preferably 300 sec. The lower limit of an average thickness of the resist film formed is preferably 10 nm, and more preferably 20 nm. The upper limit of the average thickness is preferably 1,000 nm, and more preferably 500 nm.

### Exposing Step

In this step, the resist film formed by the applying step is exposed. This exposure is carried out by irradiation with an exposure light through a photomask (as the case may be, through a liquid immersion medium such as water). Examples of the exposure light include electromagnetic waves such as a visible light ray, an ultraviolet ray, a far ultraviolet ray, EUV, an X-ray, and a γ-ray; charged particle rays such as an electron beam and a α-ray, and the like, which may be selected in accordance with a line width and the like of the intended pattern. Of these, a far ultraviolet ray, EUV, or an electron beam is preferred; an ArF excimer laser beam (wavelength: 193 nm), a KrF excimer laser beam (wavelength: 248 nm), EUV, or an electron beam is more preferred; an ArF excimer laser beam, EUV, or an electron beam is still more preferred, and EUV or an electron beam is particularly preferred.

It is preferred that post exposure baking (PEB) is carried out after the exposure to promote dissociation of the acid-labile group (a) included in the polymer (A), etc. mediated by the acid generated from the acid generator (B), etc. upon the exposure in exposed regions of the resist film. This PEB enables an increase in a difference in solubility of the resist film in a developer solution between the light-exposed regions and light-unexposed regions. The lower limit of a temperature of the PEB is preferably 50° C., more preferably 80° C., and still more preferably 100° C. The upper limit of the temperature is preferably 180° C., and more preferably 130° C. The lower limit of a time period of the PEB is preferably 5 sec, more preferably 10 sec, and still more preferably 30 sec. The upper limit of the time period is preferably 600 sec, more preferably 300 sec, and still more preferably 100 sec.

### Developing Step

In this step, the resist film exposed is developed. Accordingly, formation of a predetermined resist pattern is enabled. After the development, washing with a rinse agent such as water or an alcohol and then drying is typical. The development procedure in the developing step may be carried out by either development with an alkali, or development with an organic solvent.

In the case of the development with an alkali, the developer solution for use in the development is exemplified by aqueous alkaline solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene, 1,5-diazabicyclo-[4.3.0]-5-nonene, and the like. Of these, an aqueous TMAH solution is preferred, and a 2.38% by mass aqueous TMAH solution is more preferred.

In the case of the development with an organic solvent, the developer solution is exemplified by: an organic solvent such as a hydrocarbon solvent, an ether solvent, an ester solvent, a ketone solvent, and an alcohol solvent; a solvent containing the organic solvent; and the like. An exemplary organic solvent includes one, or two or more types of the solvents exemplified as the solvent (D) for the radiation-sensitive resin composition, and the like. Of these, the ester solvent or the ketone solvent is preferred. The ester solvent is preferably an acetic acid ester solvent, and more preferably n-butyl acetate. The ketone solvent is preferably a chain ketone, and more preferably 2-heptanone. The lower limit of the content of the organic solvent in the developer solution is preferably 80% by mass, more preferably 90% by mass, still more preferably 95% by mass, and particularly preferably 99% by mass. Components other than the organic solvent in the organic solvent developer solution are exemplified by water, silicone oil, and the like.

Examples of the development procedure include: a procedure in which the substrate is immersed for a given time period in the developer solution charged in a container (dipping procedure); a procedure in which the developer solution is placed to form a dome-shaped bead by way of the surface tension on the surface of the substrate for a given time period to conduct a development (puddle procedure); a procedure in which the developer solution is sprayed onto the surface of the substrate (spraying procedure); a procedure in which the developer solution is continuously applied onto the substrate, which is rotated at a constant speed, while scanning with a developer solution-application nozzle at a constant speed (dynamic dispensing procedure); and the like.

The resist pattern to be formed according to the resist pattern-forming method is exemplified by a line-and-space pattern, a hole pattern, and the like.

### EXAMPLES

Hereinafter, the present invention is explained in detail by way of Examples, but the present invention is not in any way limited to these Examples. Measuring methods for various types of physical properties are shown below.

### Mw, Mn, and Mw/Mn

Measurements were carried out by gel permeation chromatography (GPC) using GPC columns (“G2000 HXL” x 2, “G3000 HXL” x 1, and “G4000 HXL” x 1, each available from Tosoh Corporation) under an analytical condition involving a flow rate of 1.0 mL/min, an elution solvent of tetrahydrofuran, a sample concentration of 1.0% by mass, an injected sample amount of 100 μL, a column temperature of 40° C., and a differential refractometer as a detector, with mono-dispersed polystyrene as a standard. A dispersity index (Mw/Mn) was calculated according to measurement results of the Mw and the Mn.

### ¹³C-NMR Analysis

An analysis of determining the proportion of each structural unit contained in each polymer (mol %) was performed by using a nuclear magnetic resonance apparatus (“JNM-ECX400,” available from JEOL, Ltd.), with deuterodimethyl sulfoxide as a measurement solvent.

### Synthesis of Polymers

Monomers used for syntheses of the polymers are shown below. It is to be noted that in the following Synthesis Examples, unless otherwise specified particularly, “parts by mass” means a value, provided that the total mass of the monomers used was 100 parts by mass, and “mol %” means a value, provided that the total mol number of the monomers used was 100 mol %.

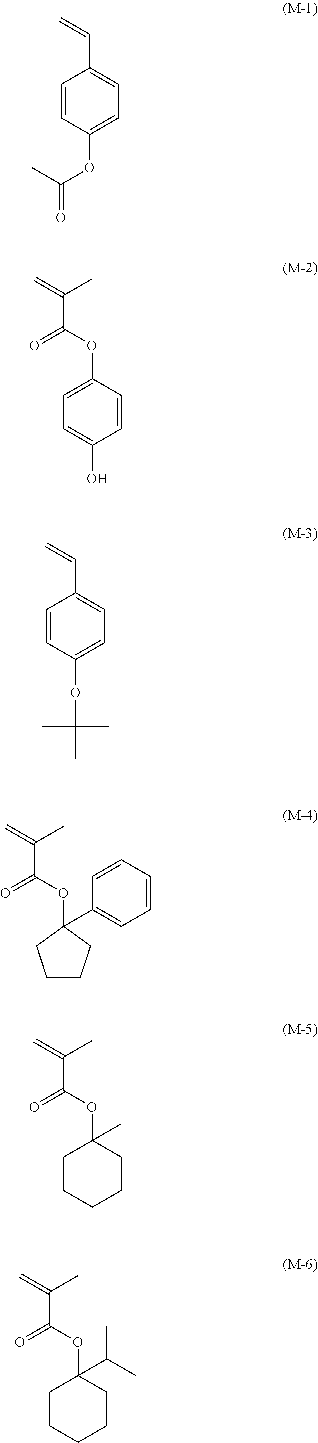 [SMILES: C=Cc1ccc(OC(C)=O)cc1 ; C=C(C)C(=O)Oc1ccc(O)cc1 ; C=Cc1ccc(OC(C)(C)C)cc1 ; C=C(C)C(=O)OC1(c2ccccc2)CCCC1 ; C=C(C)C(=O)OC1(C)CCCCC1 ; C=C(C)C(=O)OC1(C(C)C)CCCCC1]

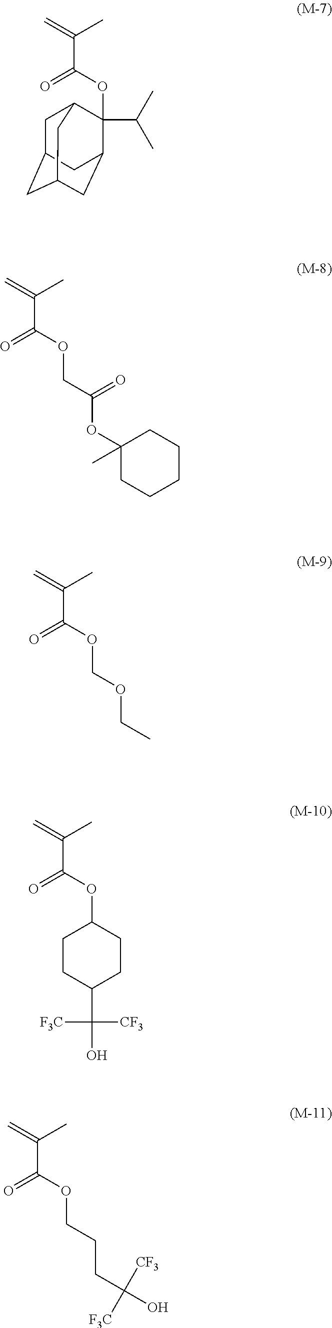

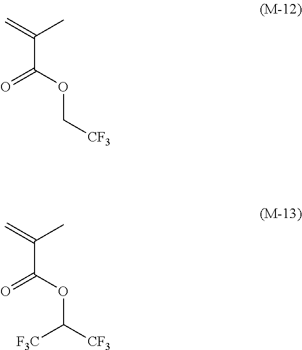

### Synthesis of Polymer (A1)

### Synthesis Example 1: Synthesis of Polymer (Aa-1)

The compound (M-1) and the compound (M-5) as monomers were dissolved in 100 parts by mass of propylene glycol monomethyl ether such that the molar percentage was 55/45. Into the mixture was added, as an initiator, azobisisobutyronitrile (AIBN) so as to be 9 mol % with respect to total monomers to prepare a monomer solution. The monomer solution was maintained in a nitrogen atmosphere at a reaction temperature of 70° C. to allow for polymerization for 16 hrs. After completion of the polymerization reaction, the polymerization solution was added dropwise into 1,000 parts by mass of n-hexane, whereby the polymer was purified through solidification. To the resultant polymer obtained by filtration were added 150 parts by mass of propylene glycol monomethyl ether. Furthermore, to the polymer were added: 150 parts by mass of methanol, triethylamine (1.5 molar equivalent with respect to the amount of the compound (M-1)), and water (1.5 molar equivalent with respect to the amount of the compound (M-1), and the mixture was subjected to a hydrolysis reaction for 8 hrs while refluxing at a boiling point was allowed. After completion of the reaction, the solvent and triethylamine were distilled off in vacuo, and the resulting polymer was dissolved in 150 parts by mass of acetone, which was then added dropwise to 2,000 parts by mass of water to permit solidification, and a produced white powder was filtered off. Drying at 50° C. for 17 hrs gave a white powdery polymer (Aa-1) with a yield of 69%. The Mw of the polymer (Aa-1) was 6,000, and the Mw/Mn was 1.65. As a result of the ¹³C-NMR analysis, the proportions of the structural units derived from (M-1) and (M-5) were, respectively, 56.1 mol % and 43.9 mol %.

### Synthesis Examples 2 to 3 and 5 to 8, and Reference Example 1: Synthesis of Polymers (Aa-2) to (Aa-3) and (Aa-5) to (Aa-9)

Polymers (Aa-2) to (Aa-3) and (Aa-5) to (Aa-9) were synthesized by a similar operation to that of Synthesis Example 1 except that each monomer of the type and in the amount shown in Table 1 below was used.

### Synthesis Example 4: Synthesis of Polymer (Aa-4)

The compound (M-2) and the compound (M-4) as monomers were dissolved in 100 parts by mass of propylene glycol monomethyl ether such that the molar percentage was 45/55. Into the mixture was added, as an initiator, azobisisobutyronitrile (AIBN) so as to be 9 mol % with respect to total monomers to prepare a monomer solution. The monomer solution was maintained in a nitrogen atmosphere at a reaction temperature of 70° C. to allow for polymerization for 16 hrs. After completion of the polymerization reaction, the polymerization solution was added dropwise into 1,000 parts by mass of n-hexane, whereby the polymer was purified through solidification, and a white powder was filtered off. Drying at 50° C. for 17 hrs gave a white powdery polymer (Aa-4) with a yield of 61%. The Mw of the polymer (Aa-4) was 6,000, and the Mw/Mn was 1.68. As a result of the ¹³C-NMR analysis, the proportions of the structural units derived from (M-2) and (M-4) were, respectively, 45.1 mol % and 54.9 mol %.

The proportion, the yield, the Mw, and the of each structural unit of each polymer thus obtained are shown together in Table 1. It is to be noted that in Table 1 below, “−” indicates that the corresponding component was not used. M-1 gives a structural unit derived from hydroxystyrene through deacetylization by a hydrolysis treatment.

TABLE 1

| | | | | | | | | Monomer that gives | | | | | | | | |
|---|---|---|---|---|---|---|---|---|---|---|---|---|---|---|---|---|
| | | | | | | | | structural unit other | | | | | | | | |
| | | | | | | | | than structural | | | | | | | | |
| | | | | | | | | unit (II) which | | | | | | | | |
| | | Monomer that gives | | | Monomer that gives | | | includes | | | Monomer that gives | | | | | |
| | | structural unit (I) | | | structural unit (II) | | | acid-labile group | | | other structural unit | | | | | |
| | (A1) | | usage | pro- | | usage | pro- | | usage | pro- | | usage | pro- | | | |
| | Poly- | | amount | portion | | amount | portion | | amount | portion | | amount | portion | Yield | | Mw/ |
| — | mer | type | (mol %) | (mol %) | type | (mol %) | (mol %) | type | (mol %) | (mol %) | type | (mol %) | (mol %) | (%) | Mw | Mn |
| Synthesis | Aa-1 | M-1 | 55 | 56.1 | M-5 | 45 | 43.9 | — | — | — | — | — | — | 69 | 6,000 | 1.65 |
| Example 1 | | | | | | | | | | | | | | | | |
| Synthesis | Aa-2 | M-1 | 40 | 43.4 | M-6 | 60 | 56.6 | — | — | — | — | — | — | 65 | 5,500 | 1.61 |
| Example 2 | | | | | | | | | | | | | | | | |
| Synthesis | Aa-3 | M-1 | 50 | 53.1 | M-7 | 50 | 46.9 | — | — | — | — | — | — | 70 | 5,500 | 1.70 |
| Example 3 | | | | | | | | | | | | | | | | |
| Synthesis | Aa-4 | M-2 | 45 | 45.1 | M-4 | 55 | 54.9 | — | — | — | — | — | — | 61 | 6,000 | 1.68 |
| Example 4 | | | | | | | | | | | | | | | | |
| Synthesis | Aa-5 | M-1 | 40 | 40.9 | M-5 | 50 | 49.9 | M-3 | 10 | 10.1 | — | — | — | 68 | 6,400 | 1.80 |
| Example 5 | | | | | | | | | | | | | | | | |
| Synthesis | Aa-6 | M-1 | 40 | 41.1 | M-6 | 50 | 48.7 | — | — | — | — | — | — | 60 | 7,000 | 1.60 |
| Example 6 | | | | | M-8 | 10 | 11.3 | | | | | | | | | |
| Synthesis | Aa-7 | M-1 | 40 | 41.2 | M-7 | 50 | 46.1 | M-9 | 10 | 13.9 | — | — | — | 55 | 7,100 | 1.53 |
| Example 7 | | | | | | | | | | | | | | | | |
| Synthesis | Aa-8 | M-1 | 40 | 40.5 | M-5 | 50 | 49.5 | — | — | — | M-10 | 10 | 10.0 | 55 | 6,800 | 1.62 |
| Example 8 | | | | | | | | | | | | | | | | |
| Reference | Aa-9 | M-1 | 45 | 44.8 | M-3 | 55 | 55.2 | — | — | — | — | — | — | 67 | 6,900 | 1.66 |
| Example 1 | | | | | | | | | | | | | | | | |

### Synthesis of Polymer (A2)

### Synthesis Example 9: Synthesis of Polymer (Ab-1)

The compound (M-10) and the compound (M-12) as monomers were dissolved in 100 parts by mass of cyclohexanone such that the molar percentage was 80/20. Into the mixture was added, as an initiator, azobisisobutyronitrile (AIBN) so as to be 4 mol % with respect to total monomers to prepare a monomer solution. The monomer solution was maintained in a nitrogen atmosphere at a reaction temperature of 85° C. to allow for polymerization for 6 hrs. After completion of the polymerization reaction, the polymerization solution was added dropwise into 1,000 parts by mass of heptane/ethyl acetate (mass ratio: 8/2), whereby the polymer was purified through solidification, and a powder was filtered off. Subsequently, a solid obtained by the filtration was washed by rinsing with 300 parts by mass of heptane/ethyl acetate (mass ratio: 8/2). Thereafter, drying at 50° C. for 17 hrs gave a white powdery polymer (Ab-1) with a favorable yield. The Mw of the polymer (Ab-1) was 9,800, and the Mw/Mn was 1.65. As a result of the ¹³C-NMR analysis, the proportions of the structural units derived from (M-10) and (M-12) were, respectively, 79.9 mol % and 20.1 mol %.

### Synthesis Examples 10 to 13 and Reference Examples 2 to 3: Synthesis of Polymers (Ab-2) to (Ab-7)

Polymers (Ab-2) to (Ab-7) were synthesized by a similar operation to that of Synthesis Example 9 except that each monomer of the type and in the amount shown in Table 2 below was used.

The proportion, the yield, the Mw, and the Mw/Mn of each structural unit of each polymer thus obtained are shown together in Table 2. It is to be noted that in Table 2 below, “−” indicates that the corresponding component was not used.

TABLE 2

| | | Monomer that gives | | | Monomer that gives | | | Monomer that gives | | | | | |
|---|---|---|---|---|---|---|---|---|---|---|---|---|---|
| | | structural unit (III) | | | structural unit (IV) | | | structural unit (V) | | | | | |
| | (A2) | | usage | pro- | | usage | pro- | | usage | pro- | | | |
| | Poly- | | amount | portion | | amount | portion | | amount | portion | Yield | | Mw/ |
| — | mer | type | (mol %) | (mol %) | type | (mol %) | (mol %) | type | (mol %) | (mol %) | (%) | Mw | Mn |
| Synthesis | Ab-1 | M-10 | 80 | 79.9 | M-12 | 20 | 20.1 | — | — | — | 72 | 9,800 | 1.65 |
| Example 9 | | | | | | | | | | | | | |
| Synthesis | Ab-2 | M-11 | 90 | 88.8 | M-13 | 10 | 11.2 | — | — | — | 69 | 11,000 | 1.60 |
| Example 10 | | | | | | | | | | | | | |
| Synthesis | Ab-3 | M-10 | 25 | 24.4 | M-12 | 5 | 4.8 | M-6 | 70 | 70.8 | 76 | 7,500 | 1.68 |
| Example 11 | | | | | | | | | | | | | |
| Synthesis | Ab-4 | M-10 | 45 | 45.1 | M-12 | 5 | 4.9 | M-5 | 50 | 50.0 | 74 | 8,600 | 1.72 |
| Example 12 | | | | | | | | | | | | | |
| Synthesis | Ab-5 | M-11 | 25 | 25.2 | M-13 | 5 | 5.0 | M-5 | 70 | 69.8 | 69 | 7,000 | 1.57 |
| Example 13 | | | | | | | | | | | | | |
| Reference | Ab-6 | M-10 | 100 | 100.0 | — | — | — | — | — | — | 80 | 8,800 | 1.75 |
| Example 2 | | | | | | | | | | | | | |
| Reference | Ab-7 | — | — | — | M-12 | 20 | 20.2 | M-5 | 80 | 79.8 | 65 | 7,000 | 1.71 |
| Example 3 | | | | | | | | | | | | | |

### Preparation of Radiation-Sensitive Resin Composition

Components other than the polymer (A1) and the polymer (A2) used for preparing the radiation-sensitive resin compositions are shown below.

### (B) Acid Generating Agent

Each structural formula is shown below.

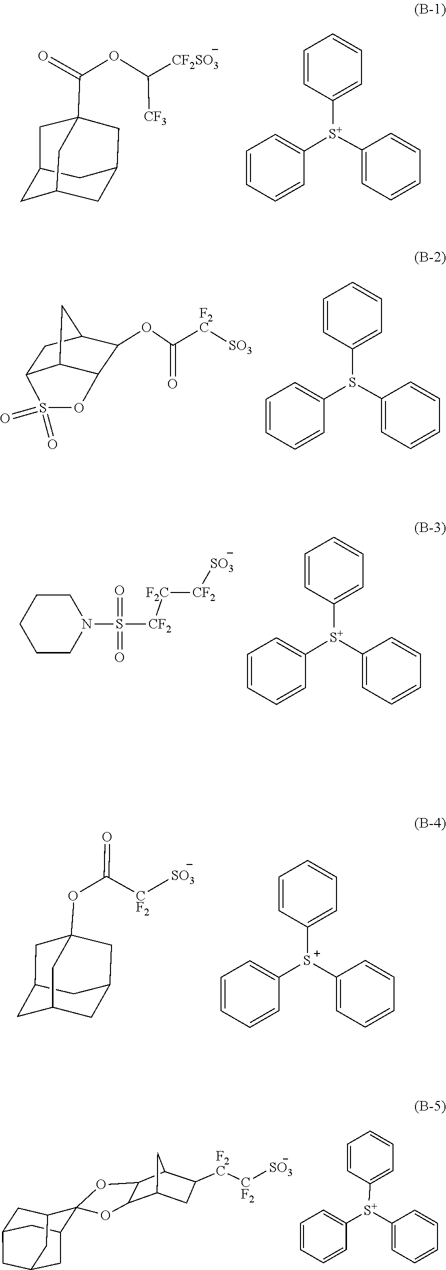

### (C) Acid Diffusion Control Agent

Each structural formula is shown below.

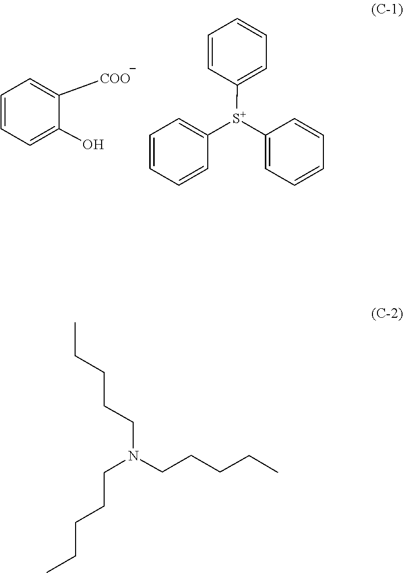

### (D) Solvent

D-1: propylene glycol monomethyl ether acetate

D-2: cyclohexanone

### Example 1

A radiation-sensitive resin composition (J-1) was prepared by: mixing 100 parts by mass of (Aa-1) as the polymer (A1), 5 parts by mass of (Ab-1) as the polymer (A2), 10 parts by mass of (B-1) as the acid generating agent (B), 3 parts by mass of (C-1) as the acid diffusion control agent (C), and 3,510 parts by mass of (D-1) and 1,510 parts by mass of (D-2) as the solvent (D); and filtering a resulting mixture through a membrane filter having a pore size of 20 μm.

### Examples 2 to 8 and Comparative Examples 1 to 3

Radiation-sensitive resin compositions (J-2) to (J-8) and (CJ-1) to (CJ-3) were prepared by a similar operation to that of Example 1, except that for each component, the type and content shown in Table 3 below were used.

TABLE 3

| | | | | | | (B) Acid | | (C) Acid diffusion | | | |
|---|---|---|---|---|---|---|---|---|---|---|---|
| | Radiation- | (A1) Polymer | | (A2) Polymer | | generating agent | | control agent | | (D) Solvent | |
| | sensitive | | content | | content | | content | | content | | content |
| | resin | | (parts by | | (parts by | | (parts by | | (parts by | | (parts by |
| — | composition | type | mass) | type | mass) | type | mass) | type | mass) | type | mass) |
| Example 1 | J-1 | Aa-1 | 100 | Ab-1 | 5 | B-1 | 10 | C-1 | 3 | D-1/D-2 | 3,510/1,510 |
| Example 2 | J-2 | Aa-2 | 100 | Ab-2 | 5 | B-1 | 10 | C-2 | 3 | D-1/D-2 | 3,510/1,510 |
| Example 3 | J-3 | Aa-3 | 100 | Ab-3 | 5 | B-2 | 10 | C-1 | 3 | D-1/D-2 | 3,510/1,510 |
| Example 4 | J-4 | Aa-4 | 100 | Ab-4 | 5 | B-3 | 15 | C-1 | 3 | D-1/D-2 | 3,510/1,510 |
| Example 5 | J-5 | Aa-5 | 100 | Ab-5 | 5 | B-4 | 15 | C-1 | 3 | D-1/D-2 | 3,510/1,510 |
| Example 6 | J-6 | Aa-6 | 100 | Ab-5 | 5 | B-5 | 20 | C-1 | 3 | D-1/D-2 | 3,510/1,510 |
| Example 7 | J-7 | Aa-7 | 100 | Ab-5 | 1 | B-5 | 20 | C-1 | 3 | D-1/D-2 | 3,510/1,510 |
| Example 8 | J-8 | An-8 | 100 | Ab-4 | 1 | B-5 | 20 | C-1 | 3 | D-1/D-2 | 3,510/1,510 |
| Comparative | CJ-1 | Aa-6 | 100 | Ab-6 | 5 | B-1 | 10 | C-1 | 3 | D-1/D-2 | 3,510/1,510 |
| Example 1 | | | | | | | | | | | |
| Comparative | CJ-2 | Aa-6 | 100 | Ab-7 | 5 | B-1 | 10 | C-1 | 3 | D-1/D-2 | 3,510/1,510 |
| Example 2 | | | | | | | | | | | |
| Comparative | CJ-3 | Aa-9 | 100 | Ab-7 | 5 | B-1 | 10 | C-1 | 3 | D-1/D-2 | 3,510/1,510 |
| Example 3 | | | | | | | | | | | |

### Resist Pattern Formation (1) (Exposure to Electron Beam, Development with Alkali)

Using a spin coater (“CLEAN TRACK ACT 8,” available from Tokyo Electron Limited), the radiation-sensitive resin compositions prepared as described above were each applied on a surface of an 8-inch silicon wafer, and PB was conducted at 110° C. for 60 sec. Thereafter, by cooling at 23° C. for 30 sec, a resist film having an average thickness of 50 nm was formed. Next, the resist film was irradiated with an electron beam by using a simplified electron beam writer (“HL800D,” available from Hitachi, Ltd.; output: 50 KeV; electric current density: 5.0 A/cm²). After the irradiating, PEB was carried out on a hot plate at 100° C. for 60 sec. Subsequently, the resist film was developed at 23° C. for 60 sec by using a 2.38% by mass aqueous TMAH solution as an alkaline developer solution, washed with water, and dried to form a positive-tone resist pattern.

### Evaluations

With regard to the resist patterns formed as described above, each radiation-sensitive resin composition was evaluated on the LWR performance, resolution, rectangularity of the cross-sectional shape, and exposure latitude by conducting the following measurements. The results of the evaluations are shown in Table 4. A scanning electron microscope (“S-9380” available from Hitachi High-Technologies Corporation) was used for line-width measurement of the resist pattern. It is to be noted that in formation of the resist pattern, an exposure dose at which a line width of 100 nm was provided (L/S=1/1) was defined as the “optimum exposure dose.”

### LWR Performance

The formed resist pattern in which the line width was 100 nm (L/S=1/1) was observed from above the pattern using the scanning electron microscope. Line widths were measured at 50 arbitrary points, and then a 3 Sigma value was determined from distribution of the measurements and defined as “LWR performance” (nm). The value being smaller reveals less line width variance, indicating better LWR performance. The LWR performance may be evaluated to be: “favorable” in a case of the LWR being no greater than 20 nm; and “unfavorable” in a case of the LWR being greater than 20 nm.

### Resolution

A dimension of a minimum resist pattern being resolved at the optimum exposure dose was measured, and the measurement value was defined as the “resolution” (nm). The value being smaller enables formation of a finer pattern, indicating a better resolution. The resolution was evaluated to be: “favorable” in a case of the resolution being no greater than 60 nm; and “unfavorable” in a case of the resolution being greater than 60 nm.

### Rectangularity of Cross-Sectional Shape

The cross-sectional shape of the resist pattern which was resolved at the optimum exposure dose was observed, a line width Lb at the middle portion in a latitudinal direction of the resist pattern and a line width La on the top portion of the resist pattern were measured, and a value La/Lb was calculated. This value was defined as an index of the rectangularity of the cross-sectional shape. With regard to the rectangularity of the cross-sectional shape, this value being closer to 1.00 indicates higher rectangularity of the cross-sectional shape of the resist pattern. The rectangularity of the cross-sectional shape may be evaluated to be: “favorable” in a case in which 0.80≤(La/Lb)≤1.20; and “unfavorable” in a case in which (La/Lb)<0.8 or 1.2<(La/Lb).

### Exposure Latitude

An exposure dose was altered stepwise by 1 μC/cm² within an exposure dose range including the optimum exposure dose, and a resist pattern was formed at each exposure dose. The line width of each resist pattern was measured using the scanning electron microscope, An exposure dose E (110) at which a line width of 110 nm was attained and an exposure dose E (90) at which a line width of 90 nm was attained were determined from the relationship between the line width obtained and the exposure dose. The exposure latitude (%) was then calculated using the following equation:

exposure latitude=[E(110)−E(90)]×100/(optimum exposure dose).

The exposure latitude value being greater indicates less variation of the dimension of the formed pattern with a variation of the exposure dose, leading to a higher process yield in the production of devices. The exposure latitude may be evaluated to be: “favorable” in a case of being no less than 20%; and “unfavorable” in a case of being less than 20%.

TABLE 4

| | | | | Rectangu- | |
|---|---|---|---|---|---|
| | | | | larity of | |
| | Radiation- | | | cross- | |
| | sensitive | LWR | | sectional | Exposure |
| | resin | performance | | Resolution | latitude |
| | composition | (nm) | shape | (nm) | (%) |
| Example 1 | J-1 | 19.2 | 57 | 1.17 | 22 |
| Example 2 | J-2 | 19.1 | 56 | 1.15 | 23 |
| Example 3 | J-3 | 14.8 | 49 | 0.95 | 26 |
| Example 4 | J-4 | 18.8 | 55 | 0.89 | 21 |
| Example 5 | J-5 | 14.6 | 48 | 1.04 | 27 |
| Example 6 | J-6 | 12.8 | 44 | 0.98 | 31 |
| Example 7 | J-7 | 12.7 | 44 | 1.01 | 32 |
| Example 8 | J-8 | 16.8 | 54 | 0.88 | 22 |
| Comparative | CJ-1 | 22.3 | 62 | 1.31 | 19 |
| Example 1 | | | | | |
| Comparative | CJ-2 | 24.4 | 61 | 1.29 | 18 |
| Example 2 | | | | | |
| Coenparative | CJ-3 | 25.0 | 62 | 1.28 | 17 |
| Example 3 | | | | | |

The results shown in Table 4 indicate that the radiation-sensitive resin compositions of the Examples result in superiority in the LWR performance, resolution, rectangularity of the cross-sectional shape, and exposure latitude. On the other hand, it is also indicated that the performance resulting from all of the radiation-sensitive resin compositions of the Comparative Examples is inferior with respect to that of the Examples.

### Resist Pattern Formation (2) (Exposure to EUV, Development with Alkali)

Each radiation-sensitive resin composition shown in Table 3 above was spin-coated on a Si substrate provided with SHB-A940, being a silicon-containing spin-on hard mask (silicon content: 43% by mass), having an average thickness of 20 nm. Prebaking was carried out at 105° C. for 60 sec by using a hot plate to produce a resist film having an average thickness of 40 nm. The resist film was subjected to exposure by using “NXE3300,” an EUV scanner manufactured by ASML Co., (NA=0.33; σ=0.9/0.4; dipole illumination, with a line pattern mask having a pitch of 36 nm in terms of the dimension on the wafer). PEB was carried out at a 110° C. for 60 sec on a hot plate, and then a development was carried out using a 2.38% by mass aqueous TMAH solution for 30 sec, whereby a line pattern having a dimension of 18 nm was obtained.

### Evaluations

The resist pattern thus obtained was evaluated as follows.

### Depth of Focus (DOF) Evaluation

An exposure dose when a line dimension of 18 nm was formed was determined using a line width SEM (CG5000) manufactured by Hitachi High-Technologies Corporation and defined as the sensitivity. On a resist pattern resolved at the sensitivity, the dimension when the focus was shifted along the depth direction was observed, and a latitude (depth of focus (DOF)) of the depth direction at which the line dimension falls within ±10% of the standard while not accompanied by a bridge and/or residue was measured. With regard to the DOF performance, a higher value indicates less variation in the line dimension formed with shifting of the focus position, leading to a higher process yield in the production of devices. The DOF performance can be evaluated to be: “favorable” in a case of being no less than 100 nm; and “unfavorable” in a case of being no greater than 100 nm.

TABLE 5

| | Radiation-sensitive | DOF performance |
|---|---|---|
| | resin composition | (nm) |
| Example 1 | J-1 | 120 |
| Example 2 | J-2 | 120 |
| Example 3 | J-3 | 160 |
| Example 4 | J-4 | 130 |
| Example 5 | J-5 | 160 |
| Example 6 | J-6 | 200 |
| Example 7 | J-7 | 200 |
| Example 8 | J-8 | 140 |
| Comparative Example 1 | CJ-1 | 80 |
| Comparative Example 2 | CJ-2 | 60 |
| Comparative Example 3 | CJ-3 | 70 |

As is clear from the results shown in Table 5, by the EUV exposure, all of the radiation-sensitive resin compositions of the Examples were superior in the DOF performance.

The radiation-sensitive resin composition and the resist pattern-forming, method of the embodiments of the present invention enable a resist pattern to be formed being superior in LWR performance, resolution, rectangularity of the cross-sectional shape, exposure latitude, and depth of focus. Therefore, these can be suitably used in the manufacture of semiconductor devices, in which further progress of miniaturization is expected in the future.

Obviously, numerous modifications and variations of the present invention are possible in light of the above teachings. It is therefore to be understood that within the scope of the appended claims, the invention may be practiced otherwise than as specifically described herein.

What is claimed is:

1. A radiation-sensitive resin composition comprising:
a first polymer comprising a first structural unit which comprises a phenolic hydroxyl group, and a second structural unit which comprises an acid-labile group and a carboxy group which is protected by the acid-labile group;
a second polymer comprising a third structural unit represented by formula (S-1), and a fourth structural unit which is a structural unit other than the third structural unit and is represented by formula (S-2); and
a radiation-sensitive acid generator, wherein
the acid-labile group comprises a monocyclic or polycyclic ring structure having no fewer than 3 and no more than 20 ring atoms, 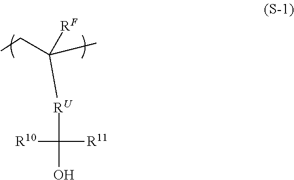
wherein, in the formula (S-1), R^{F} represents a hydrogen atom, a fluorine atom, or a monovalent organic group having 1 to 20 carbon atoms; R^{U} represents a single bond or a divalent organic group having 1 to 20 carbon atoms; R¹⁰ represents a fluorine atom or a monovalent fluorinated hydrocarbon group having 1 to 20 carbon atoms; and R¹¹ represents a hydrogen atom, a fluorine atom, a monovalent hydrocarbon group having 1 to 20 carbon atoms, or a monovalent fluorinated hydrocarbon group having 1 to 20 carbon atoms, and 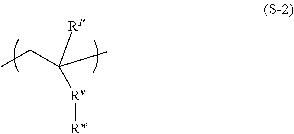
in the formula (S-2), R^{G} represents a hydrogen atom, a fluorine atom, or a monovalent organic group having 1 to 20 carbon atoms; R^{V} represents a single bond or a divalent organic group having 1 to 20 carbon atoms; and R^{W} represents a monovalent organic group having 1 to 20 carbon atoms which comprises a fluorine atom and does not comprise an alkali-labile group.

2. The radiation-sensitive resin composition according to claim 1, wherein
the second polymer further comprises a fifth structural unit which comprises an acid-labile group, and
a molar percentage of the fifth structural unit in the second polymer is greater than a sum of: in the first polymer, a molar percentage of the second structural unit, and a molar percentage of a structural unit which is a structural unit other than the second structural unit and comprises the acid-labile group.

3. The radiation-sensitive resin composition according to claim 2, wherein
the molar percentage of the fifth structural unit in the second polymer is 45 mol % or more.

4. The radiation-sensitive resin composition according to claim 2, wherein
the molar percentage of the fifth structural unit in the second polymer is 55 mol % or more.

5. The radiation-sensitive resin composition according to claim 2, wherein the second structural unit and the fifth structural unit are each independently represented by formula (S-3): 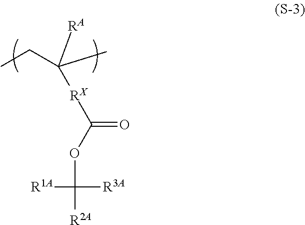
wherein, in the formula (S-3), R^{A} represents a hydrogen atom, a fluorine atom, or a monovalent organic group having 1 to 20 carbon atoms; R^{X} represents a single bond or a divalent organic group having 1 to 20 carbon atoms; R^{1A} represents a hydrogen atom or a monovalent organic group having 1 to 20 carbon atoms; R^{2A} represents a monovalent hydrocarbon group having 1 to 20 carbon atoms and R^{3A} represents a monovalent organic group having 1 to 20 carbon atoms, or R^{2A} and R^{3A} taken together represent a monocyclic or polycyclic ring structure having 3 to 20 ring atoms together with the carbon atom to which R^{2A} and R^{3A} bond, wherein in a case in which R^{2A} represents the monovalent hydrocarbon group having 1 to 20 carbon atoms and R^{3A} represents the monovalent organic group having 1 to 20 carbon atoms, at least one of R^{1A}, R^{2A}, and R^{3A} comprises a monocyclic or polycyclic ring structure having 3 to 20 ring atoms.

6. The radiation-sensitive resin composition according to claim 5, wherein
R^{1A} in the formula (S-3) in the second structural unit represents an alkyl group having no fewer than 3 carbon atoms, and
R^{1A} in the formula (S-3) in the fifth structural unit represents an alkyl group having no fewer than 2 carbon atoms.

7. The radiation-sensitive resin composition according to claim 1, which is suitable for an exposure to an extreme ultraviolet ray or an exposure to an electron beam.

8. A resist pattern-forming method comprising:
forming a resist film directly or indirectly on a substrate by applying the radiation-sensitive resin composition according to claim 1;
exposing the resist film; and
developing the resist film exposed.

9. The resist pattern-forming method according to claim 8, wherein in the exposing, the resist film is exposed to an extreme ultraviolet ray or an electron beam.

10. The resist pattern-forming method according to claim 8, wherein
the second polymer further comprises a fifth structural unit which comprises an acid-labile group, and
a molar percentage of the fifth structural unit in the second polymer is greater than a sum of: in the first polymer, a molar percentage of the second structural unit, and a molar percentage of a structural unit which is a structural unit other than the second structural unit and comprises the acid-labile group.

11. The resist pattern-forming method according to claim 10, wherein
the molar percentage of the fifth structural unit in the second polymer is 45 mol % or more.

12. The resist pattern-forming method according to claim 10, wherein
the molar percentage of the fifth structural unit in the second polymer is 55 mol % or more.

13. The resist pattern-forming, method according to claim 10, wherein the second structural unit and the fifth structural unit are each independently represented by formula (S-3): 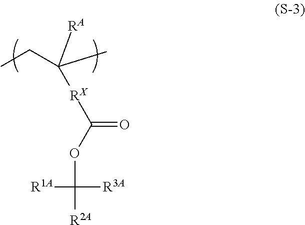
wherein, in the formula (S-3), R^{A} represents a hydrogen atom, a fluorine atom, or a monovalent organic group having 1 to 20 carbon atoms; R^{X} represents a single bond or a divalent organic group having 1 to 20 carbon atoms; R^{1A} represents a hydrogen atom or a monovalent organic group having 1 to 20 carbon atoms; R^{2A} represents a monovalent hydrocarbon group having 1 to 20 carbon atoms and R^{3A} represents a monovalent organic group having 1 to 20 carbon atoms, or R^{2A} and R^{3A} taken together represent a monocyclic or polycyclic ring structure having 3 to 20 ring atoms together with the carbon atom to which R^{2A} and R^{3A} bond, wherein in a case in which R^{2A} represents the monovalent hydrocarbon group having 1 to 20 carbon atoms and R^{3A} represents the monovalent organic group having 1 to 20 carbon atoms, at least one of R^{1A}, R^{2A}, and R^{3A} comprises a monocyclic or polycyclic ring structure having 3 to 20 ring atoms.

14. The resist pattern-forming method according to claim 13, wherein
R^{1A} in the formula (S-3) in the second structural unit represents an alkyl group having no fewer than 3 carbon atoms, and
R^{1A} in the formula (S-3) in the fifth structural unit represents an alkyl group having no fewer than 2 carbon atoms.
